(19) United States
(12) Patent Application Publication
(10) Pub. No.: US 2013/0092929 A1
(43) Pub. Date: Apr. 18, 2013

(54) SEMICONDUCTOR DEVICE AND MANUFACTURING METHOD THEREOF

(71) Applicant: SEMICONDUCTOR ENERGY LABORATORY CO., Atsugi-shi (JP)

(72) Inventors: Kenichi OKAZAKI, Tochigi (JP); Toshiyuki MIYAMOTO, Kanuma (JP); Takashi HAMOCHI, Shimotsuga (JP); Masafumi NOMURA, Tochigi (JP)

(73) Assignee: SEMICONDUCTOR ENERGY LABORATORY CO., LTD., Atsugi-shi (JP)

(21) Appl. No.: 13/649,645

(22) Filed: Oct. 11, 2012

(30) Foreign Application Priority Data
Oct. 14, 2011 (JP) 2011-227163

(51) Int. Cl. H01L 29/78; H01L 21/336

(52) U.S. Cl. 257/43; 438/104; 257/E29.255; 257/E21.409

(57) ABSTRACT

In a transistor using an oxide semiconductor, entry of hydrogen atoms into an oxide semiconductor film adversely affects reliability. Water is a typical substance including a hydrogen atom, which could enter a semiconductor device after manufacture. Thus, an object of the invention is to reduce the amount of substances including a hydrogen atom, particularly water, entering a semiconductor device using an oxide semiconductor. It was found that a silicon oxynitride film with high density sufficiently prevents entry of water, and does not swell much even in the atmosphere containing water. Accordingly, a silicon oxynitride film with high density is provided as a protective film so as to prevent entry of water into a semiconductor device using an oxide semiconductor. Specifically, a silicon oxynitride film used as the protective film has a density of 2.32 g/cm³ or more.

### TECHNICAL FIELD

The present invention relates to a semiconductor device.

### BACKGROUND ART

In recent years, transistors using an oxide semiconductor for channel regions have attracted attention. The transistors using an oxide semiconductor for channel regions have many advantages as compared to transistors using amorphous silicon (for example, Patent Document 1): higher field-effect mobility, lower off-state current, and the like. Patent Document 2 discloses a transistor utilizing such a feature of an oxide semiconductor.

### REFERENCE

### Patent Document

[Patent Document 1] Japanese Published Patent Application No. 2001-15764
[Patent Document 2] Japanese Published Patent Application No. 2011-9719

### DISCLOSURE OF INVENTION

However, as disclosed in Patent Document 2, it is known that entry of hydrogen atoms into an oxide semiconductor film adversely affects the characteristics of a transistor using an oxide semiconductor. The adverse effect of hydrogen atoms on the transistor using an oxide semiconductor is serious and contrasts with positive influence of hydrogen atoms on a transistor using amorphous silicon.

As substances including a hydrogen atom, which could enter a semiconductor device including a transistor after manufacture, water found in large quantities in the air can be given primarily. Accordingly, it is needed to reduce the amount of water which enters a semiconductor device using an oxide semiconductor.

Thus, an object of one embodiment of the present invention is to reduce the amount of substances including a hydrogen atom, particularly water, entering a semiconductor device using an oxide semiconductor.

As a method for preventing entry of water into a semiconductor device, a protective film (also referred to as a barrier film, a passivation film, and the like) can be provided around a transistor. As the protective film, an aluminum oxide film, a silicon nitride film, a silicon nitride oxide film, a silicon oxynitride film, or the like can be used.

However, the aluminum oxide film has a lot of fixed charges and high dielectric constant leading to easy occurrence of parasitic capacitance, and such features might cause a problem in the performance of a transistor. Furthermore, in a manufacturing process of a semiconductor device, the aluminum oxide film is formed by sputtering and thus has a disadvantage of low productivity as compared to a film which can be formed by CVD.

The silicon nitride film and the silicon nitride oxide film can be formed by CVD and thus have high productivity. However, the silicon nitride film and the silicon nitride oxide film have the features such as a lot of hydrogen atoms contained in the film, a lot of fixed charges, high dielectric constant, and large inner stress. In particular, hydrogen atoms contained in the films adversely affect a transistor using an oxide semiconductor; therefore, these films are not preferably used as a film around a transistor using an oxide semiconductor.

On the other hand, the silicon oxynitride film can be formed by CVD and thus has high productivity, and further, the silicon oxynitride film is advantageous in that its deposition method is established because the film has been used in a semiconductor device using amorphous silicon for a long time, and a film with a few fixed charges can be formed. In addition, the number of hydrogen atoms in the film is smaller than that in the silicon nitride film and the silicon nitride oxide film. A conventional silicon oxynitride film, however, is disadvantageous in that entry of water cannot be sufficiently prevented and the film swells in the atmosphere containing water.

Thus, the inventors have conducted diligent studies and found that a silicon oxynitride film with high density sufficiently prevents entry of water, does not swell much even in the atmosphere containing water, and thus is preferably used as a protective film. This contrasts with a conventional idea that a protective film is preferably a porous film for reducing the dielectric constant.

The present invention has focused on a silicon oxynitride film with high density, which is provided as a protective film of a transistor and prevents water from entering a semiconductor device using an oxide semiconductor.

One embodiment of the present invention is a semiconductor device including a transistor having a gate electrode, an oxide semiconductor film over the gate electrode, a gate insulating film between the gate electrode and the oxide semiconductor film, and a source electrode and a drain electrode which are in contact with the oxide semiconductor film; a silicon oxide film over the transistor; and a silicon oxynitride film over the silicon oxide film. The silicon oxynitride film has a density of 2.32 g/cm³ or more.

Another embodiment of the present invention is a semiconductor device including a transistor having a gate electrode, an oxide semiconductor film over the gate electrode, a gate insulating film between the gate electrode and the oxide semiconductor film, and a source electrode and a drain electrode which are in contact with the oxide semiconductor film; a silicon oxide film over the transistor; and a silicon oxynitride film over the silicon oxide film. The silicon oxynitride film has a swelling ratio of 4 volume % or less after a test at a temperature of 130° C. and a relative humidity of 100% for 12 hours.

Another embodiment of the present invention is a semiconductor device including a silicon oxynitride film; a silicon oxide film over the silicon oxynitride film; and a transistor having an oxide semiconductor film over the silicon oxide film, a gate electrode over the oxide semiconductor film, a gate insulating film between the oxide semiconductor film and the gate electrode, and a source electrode and a drain electrode which are in contact with the oxide semiconductor film. The silicon oxynitride film has a density of 2.32 g/cm³ or more.

Another embodiment of the present invention is a semiconductor device including a silicon oxynitride film; a silicon oxide film over the silicon oxynitride film; and a transistor having an oxide semiconductor film over the silicon oxide film, a gate electrode over the oxide semiconductor film, a gate insulating film between the oxide semiconductor film and the gate electrode, and a source electrode and a drain electrode which are in contact with the oxide semiconductor film. The silicon oxynitride film has a swelling ratio of 4 volume % or less after a pressure cooker test at a temperature of 130° C. and a relative humidity of 100% for 12 hours.

When the spectrum of the silicon oxynitride film is measured by Fourier transform infrared spectroscopy, a Si—O—Si bond stretching mode may have a peak at 1056 cm⁻¹ or more.

According to one embodiment of the present invention, it is possible to reduce the amount of substances containing hydrogen atoms, particularly water, which enters a semiconductor device using an oxide semiconductor.

### BRIEF DESCRIPTION OF DRAWINGS

In the accompanying drawings:

FIGS. 1A and 1B are respectively a top view and a cross-sectional view showing one mode of a semiconductor device;

FIGS. 2A to 2E are cross-sectional views showing one mode of a semiconductor device;

FIGS. 3A to 3D are cross-sectional views showing one mode of a semiconductor device;

FIGS. 4A to 4D are cross-sectional views showing a method for manufacturing one mode of a semiconductor device;

FIGS. 5A and 5B are cross-sectional views showing a method for manufacturing one mode of a semiconductor device;

FIGS. 6A to 6C are top views showing one mode of a semiconductor device;

FIG. 7 is a cross-sectional view showing one mode of a semiconductor device;

FIG. 8 is a cross-sectional view showing one mode of a semiconductor device;

FIGS. 9A to 9F are views showing electronic apparatuses;

FIG. 10 is a graph showing the relation between the flow rate ratio of silane to nitrous oxide and density;

FIG. 11 is a graph showing the relation between density and swelling ratio;

FIG. 12A is a graph showing the infrared absorption spectra of silicon oxynitride films, FIG. 12B is a graph showing the relation between the flow rate ratio of silane to nitrous oxide and a peak wavenumber, and FIG. 12C is a graph showing the relation between the flow rate ratio of silane to nitrous oxide and a swelling ratio;

FIG. 13A is a graph showing the infrared absorption spectra of silicon oxynitride films, FIG. 13B is a graph showing the relation between the flow rate ratio of silane to nitrous oxide and a peak wavenumber, and FIG. 13C is a graph showing the relation between the flow rate ratio of silane to nitrous oxide and a swelling ratio;

FIG. 14 is a schematic diagram of a semiconductor device manufactured in Example 3;

FIGS. 15A and 15B are graphs respectively showing a threshold voltage and a shift value;

FIG. 16 is a graph showing the relation between power and the amount of change in shift value and threshold value;

FIG. 17 is a graph showing the relation between the flow rate ratio of silane to nitrous oxide and the amount of change in shift value and threshold value; and

FIG. 18 is a graph showing the relation between the flow rate ratio of silane to nitrous oxide and the amount of change in shift value and threshold value.

### BEST MODE FOR CARRYING OUT THE INVENTION

Examples of embodiments of the present invention will be described below with reference to drawings. Note that the present invention is not limited to the following description, and it is apparent to those skilled in the art that modes and details can be modified in various ways without departing from the spirit and scope of the present invention. Therefore, the present invention is not construed as being limited to the description of the embodiments given below.

Note that the position, size, range, or the like of each component illustrated in drawings and the like is not accurately represented in some cases for easy understanding. Therefore, the disclosed invention is not necessarily limited to the position, size, range, or the like as disclosed in the drawings and the like.

It is also noted that in this specification and the like, ordinal numbers such as “first”, “second”, and “third” “are” used in order to avoid confusion among components, and the terms do not limit the components numerically.

Further, in this specification and the like, the term such as “electrode” or “wiring” does not limit the function of such a component. For example, an “electrode” is sometimes used as part of a “wiring”, and vice versa. Furthermore, the term “electrode” or “wiring” can include the case where a plurality of “electrodes” or “wirings” are formed in an integrated manner.

Also in this specification and the like, a silicon oxynitride film is a film containing oxygen, nitrogen, and silicon as its components and containing more oxygen than nitrogen. A silicon nitride oxide film is a film containing nitrogen, oxygen, and silicon as its components and containing more nitrogen than oxygen. A silicon oxide film is a film containing oxygen and silicon as its components.

For example, a silicon oxynitride film refers to a film containing oxygen in the range of 50 at. % to 70 at. % inclusive, nitrogen in the range of 0.5 at. % to 15 at. % inclusive, silicon in the range of 25 at. % to 35 at. % inclusive, and hydrogen in the range of 0 at. % to 10 at. % inclusive. A silicon nitride oxide film refers to a film containing oxygen in the range of 5 at. % to 30 at. % inclusive, nitrogen in the range of 20 at. % to 55 at. % inclusive, silicon in the range of 25 at. % to 35 at. % inclusive, and hydrogen in the range of 10 at. % to 25 at. % inclusive. A silicon oxide film refers to a film containing oxygen in the range of 50 at. % to 70 at. % inclusive, nitrogen in the range of 0 at. % to 0.5 at. % inclusive, silicon in the range of 25 at. % to 35 at. % inclusive, hydrogen in the range of 0 at. % to 5 at. % inclusive, and argon in the range of 0 at. % to 5 at. % inclusive.

Note that the above ranges are obtained in the case where measurement is performed using Rutherford backscattering spectrometry (RBS) and hydrogen forward scattering spectrometry (HFS). In addition, the total of the percentages of the constituent elements does not exceed 100 at. %.

In addition, functions of a “source” and a “drain” are sometimes replaced with each other when a transistor of opposite conductivity type is used or when the direction of current flowing is changed in circuit operation, for example. Therefore, the terms “source” and “drain” can be replaced with each other in this specification.

### Embodiment 1

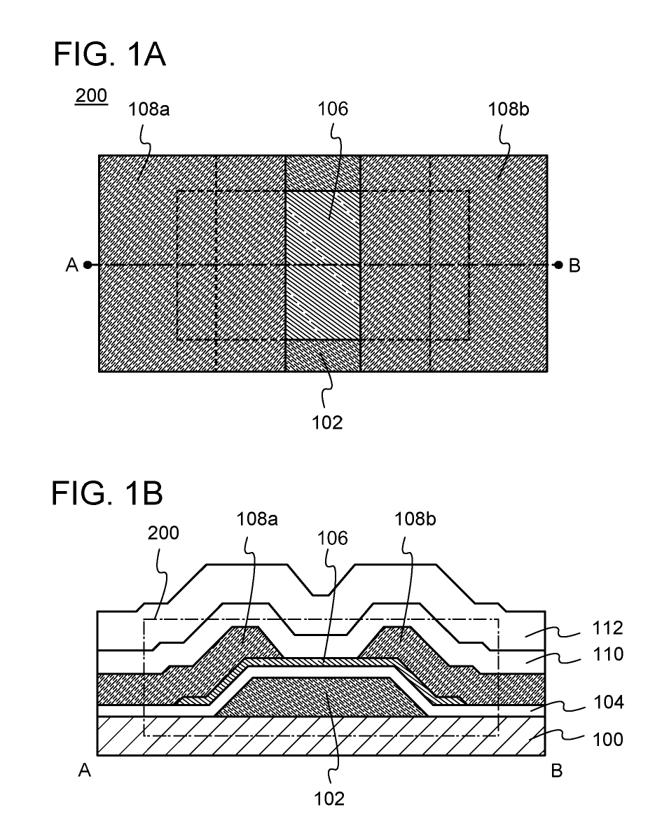

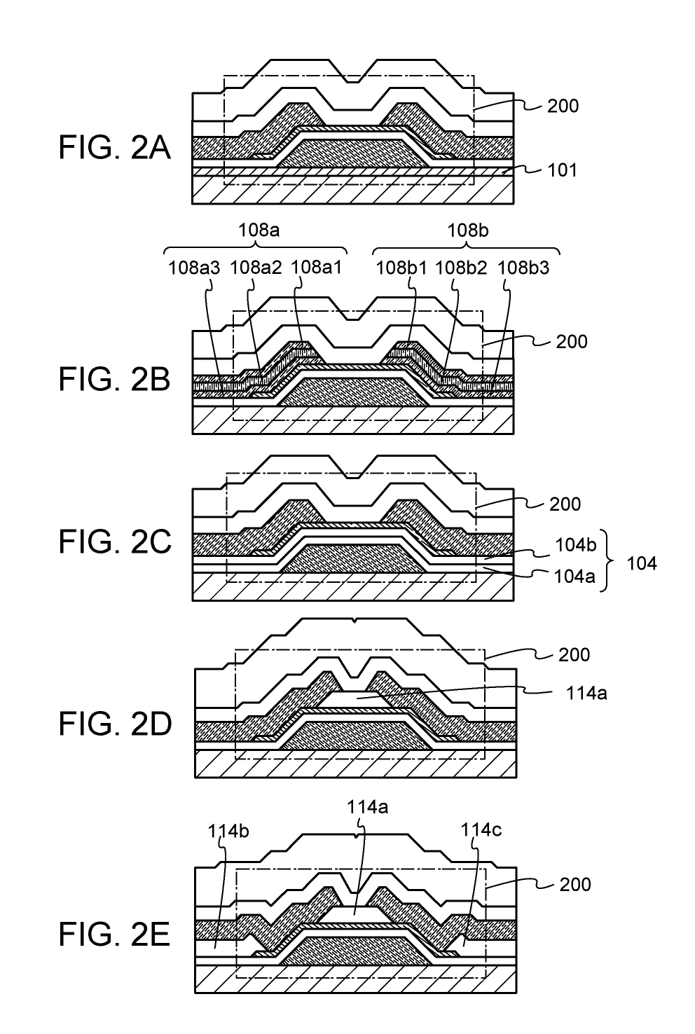

In this embodiment, an example of a semiconductor device according to one embodiment of the present invention will be described with reference to FIGS. 1A and 1B and FIGS. 2A to 2E.

FIGS. 1A and 1B are cross-sectional views of a semiconductor device including a transistor 200. The transistor 200 includes a gate electrode 102 over a substrate 100 having an insulating surface; an oxide semiconductor film 106 over the gate electrode 102; a gate insulating film 104 between the gate electrode 102 and the oxide semiconductor film 106; and a source or drain electrode 108a and a drain or source electrode 108b which are in contact with the oxide semiconductor film 106. In addition, a protective film is provided over the transistor 200. More specifically, a first protective film 110 is provided in contact with the oxide semiconductor film 106, and a second protective film 112 is provided over the first protective film 110.

Among the stacked protective films, the second protective film 112 which is outward of the transistor 200 is formed using a silicon oxynitride film with high density, specifically, with a density of 2.32 g/cm³ or more, preferably 2.36 g/cm³ or more.

When the silicon oxynitride film has an increased density, the film sufficiently prevents entry of water and does not swell much even in the atmosphere containing water. Specifically, when the silicon oxynitride film has high density, a swelling ratio of 4 volume % or less, preferably 2 volume % or less can be achieved after an acceleration test such as a pressure cooker test (PCT) or a highly accelerated stress test (HAST).

Note that the PCT and the HAST are performed under the following conditions unless otherwise specified in this specification and the like.

PCT: temperature, 130° C.; relative humidity, 100%; test time, 12 hours
HAST: temperature, 130° C.; relative humidity, 85%; test time, 12 hours

The swelling ratio of the silicon oxynitride film is obtained using the following formula I, where the film thicknesses before and after the test such as the PCT or the HAST are measured with a spectroscopic ellipsometer.

Swelling ratio (volume %)=(film thickness after test−film thickness before test)/(film thickness before test)×100 (formula 1)

Note that the means for measuring the film thickness is not limited to the spectroscopic ellipsometer, and an X-ray Reflectometer (XRR), a transmission electron microscope (TEM), or the like may be used.

The use of the silicon oxynitride film with high density for the second protective film 112 allows a reduction in the amount of water entering the semiconductor device including the transistor 200. Accordingly, entry of hydrogen atoms into the oxide semiconductor film 106 can be reduced, resulting in a prevention of a variation in the characteristics of the transistor 200.

In the semiconductor device including the transistor 200 of FIGS. 1A and 1B, the two protective films (the first protective film 110 and the second protective film 112) are stacked. In the case where the protective films are stacked in this manner, entry of water into the semiconductor device can be more sufficiently prevented by using the silicon oxynitride film with high density for the protective film outward of the transistor, namely, the second protective film 112.

Further, among the stacked protective films, the first protective film 110 touching the oxide semiconductor film 106 is preferably formed using an insulating film from which oxygen is released by heat. When the oxide semiconductor film 106 is in contact with the insulating film from which oxygen is released by heat, oxygen can be released from the insulating film and diffused into (or supplied to) the oxide semiconductor in the heat treatment step described later. Accordingly, the density of oxygen vacancies in the oxide semiconductor can be reduced, and the interface state density between the insulating film and the oxide semiconductor can be reduced. As a result, electric charge which may be generated owing to operation of the transistor or the like can be prevented from being captured at the interface between the insulating film and the oxide semiconductor. It is thus possible to prevent, for example, shift of the threshold voltage in the negative direction in the case where the transistor 200 is an n-channel transistor.

The transistor using an oxide semiconductor tends to be normally on because of its difficulty in controlling the threshold voltage. However, by providing the first protective film 110 in contact with the oxide semiconductor film 106, the density of oxygen vacancies can be reduced and a normally-off transistor can be easily obtained.

The insulating film from which oxygen is released by heat preferably contains oxygen at a proportion exceeding the stoichiometric proportion. The insulating film can be made of silicon oxide, silicon oxynitride, silicon nitride oxide, aluminum oxide, aluminum oxynitride, gallium oxide, hafnium oxide, yttrium oxide, or the like.

In this embodiment, the first protective film 110 is formed using a silicon oxide film from which oxygen can be released by heat.

When the first protective film 110 and the second protective film 112 are thus stacked over the transistor 200, a normally-off transistor with stable electric characteristics can be easily obtained.

An oxide semiconductor to be used for the oxide semiconductor film 106 preferably contains at least indium (In) or zinc (Zn). In particular, In and Zn are preferably contained. A stabilizer for strongly bonding oxygen is preferably contained in addition to In and Zn. As a stabilizer, at least one of gallium (Ga), tin (Sn), hafnium (Hf), and aluminum (Al) may be contained.

As another stabilizer, one or plural kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu) may be contained.

As the oxide semiconductor, the following can be used, for example: a four-component metal oxide such as an In—Sn—Ga—Zn-based oxide; a three-component metal oxide such as an In—Ga—Zn-based oxide, an In—Sn—Zn-based oxide, an In—Al—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide; a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide; or a one-component metal oxide such as an In-based oxide, a Sn-based oxide, or a Zn-based oxide.

Note that here, for example, an In—Ga—Zn-based oxide means an oxide containing In, Ga, and Zn as its main component, in which there is no particular limitation on the ratio of In:Ga:Zn.

Alternatively, a material represented by InMO₃(ZnO)ₘ (m>0) may be used as the oxide semiconductor. Note that M represents one or more metal elements selected from Ga, Fe, Mn, and Co. As the oxide semiconductor, a material represented by In₂SnO₅(ZnO), (n>0) may also be used.

For example, an In—Ga—Zn-based oxide with an atomic ratio of In:Ga:Zn=3:1:2, 1:1:1, or 2:2:1, or an oxide whose atomic ratio is in the neighborhood of the above atomic ratios can be used. Alternatively, an In—Sn—Zn-based oxide with an atomic ratio of In:Sn:Zn=1:1:1, 2:1:3, or 2:1:5, or an oxide whose atomic ratio is in the neighborhood of the above atomic ratios can be used.

Note that for example, the expression “the composition of an oxide including In, Ga, and Zn at the atomic ratio, In:Ga:Zn=a:b:c (a+b+c=1), is in the neighborhood of the composition of an oxide including In, Ga, and Zn at the atomic ratio, In:Ga:Zn=A:B:C (A+B+C=1)” means that a, b, and c satisfy the following relation: (a−A)²+(b−B)²+(c−C)²≦r², and r may be 0.05, for example. The same applies to other oxides.

However, the composition of the oxide semiconductor is not limited to those described above, and an oxide semiconductor having an appropriate composition may be used depending on the required semiconductor characteristics (e.g., field-effect mobility or threshold voltage). In order to obtain the needed semiconductor characteristics, the carrier concentration, the impurity concentration, the defect density, the atomic ratio between a metal element and oxygen, the interatomic distance, the density, and the like are preferably set to appropriate values.

When an oxide semiconductor is highly purified, the off-state current of a transistor using such an oxide semiconductor for a channel region can be sufficiently reduced (the off-state current means here a drain current when a potential difference between a source and a gate is equal to or lower than the threshold voltage in the off state, for example). A highly purified oxide semiconductor can be obtained, for example, in such a manner that film deposition is performed by heat treatment so as to prevent hydrogen or a hydroxyl group which is an impurity adversely affecting the oxide semiconductor from being contained in the film, or heat treatment is performed after film deposition so as to remove the impurity from the film. In the case where a highly purified In—Ga—Zn-based-oxide semiconductor is used for a channel region of a transistor having a channel length of 10 μm, a semiconductor film thickness of 30 nm, and a drain voltage of about 1 V to 10 V, the off-state current of the transistor can be reduced to 1×10⁻¹³ A or less. In addition, the off-state current per channel width (the value obtained by dividing the off-state current by the channel width of the transistor) can be made about 1×10⁻²³ A/μm (10 yA/μm) to 1×10⁻²² A/m (100 yA/μm).

The oxide semiconductor is a non-single-crystal semiconductor, and preferably has crystallinity. The oxide semiconductor may be either amorphous or polycrystalline, and is not necessarily a completely amorphous semiconductor; for example, a crystalline region may be included in an amorphous region.

Further, the oxide semiconductor film 107 is preferably a CAAC-OS (c-axis aligned crystalline oxide semiconductor) film.

The CAAC-OS film is not completely single crystal nor completely amorphous. The CAAC-OS film is an oxide semiconductor film with a crystal-amorphous mixed phase structure where crystal parts and amorphous parts are included. Note that in most cases, the crystal part fits inside a cube whose one side is less than 100 nm. From an observation image obtained with a transmission electron microscope (TEM), the boundary between an amorphous part and a crystal part in the CAAC-OS film is not clear. Further, with the TEM, a grain boundary in the CAAC-OS film is not found. Thus, in the CAAC-OS film, a reduction in electron mobility, due to the grain boundary, is suppressed.

In each of the crystal parts included in the CAAC-OS film, a c-axis is aligned in a direction parallel to a normal vector of a surface on which the CAAC-OS film is formed or a normal vector of a surface of the CAAC-OS film, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis. Note that, among the crystal parts, the directions of the a-axis and the b-axis of one crystal part may be different from those of another crystal part. In this specification, a simple term “perpendicular” includes a range from 85° to 95°. In addition, a simple term “parallel” includes a range from −5° to 5°.

In the CAAC-OS film, distribution of crystal parts is not necessarily uniform. For example, in the formation process of the CAAC-OS film, in the case where crystal growth occurs from a surface side of the oxide semiconductor film, the proportion of crystal parts in the vicinity of the surface of the oxide semiconductor film is higher than that in the vicinity of the surface on which the oxide semiconductor film is formed in some cases. Further, when an impurity is added to the CAAC-OS film, the crystal part in a region to which the impurity is added becomes amorphous in some cases.

Since the c-axes of the crystal parts included in the CAAC-OS film are aligned in the direction parallel to a normal vector of a surface on which the CAAC-OS film is formed or a normal vector of a surface of the CAAC-OS film, the directions of the c-axes may be different from each other depending on the shape of the CAAC-OS film (the cross-sectional shape of the surface on which the CAAC-OS film is formed or the cross-sectional shape of the surface of the CAAC-OS film). Note that when the CAAC-OS film is formed, the direction of c-axis of the crystal part is in parallel to a normal vector of the surface on which the CAAC-OS film is formed or a normal vector of the surface of the CAAC-OS film. The crystal part is formed by deposition or by performing treatment for crystallization such as heat treatment after deposition.

In this embodiment, the oxide semiconductor film 106 is formed using an oxide semiconductor with an atomic ratio of In:Ga:Zn=1:1:1.

There is no particular limitation on a material and the like of the substrate 100 as long as the material has heat resistance high enough to withstand at least heat treatment performed later. For example, a glass substrate, a ceramic substrate, a quartz substrate, or a sapphire substrate may be used as the substrate 100. Alternatively, a single crystal semiconductor substrate or a polycrystalline semiconductor substrate made of silicon carbide or the like; a compound semiconductor substrate made of silicon germanium, gallium nitride, or the like; or the like may be used as the substrate 100. Still alternatively, any of these substrates provided with a semiconductor element may be used as the substrate 100. Further alternatively, any of these substrates provided with an insulating film 101 may be used as shown in FIG. 2A.

The gate electrode 102, the source or drain electrode 108a, and the drain or source electrode 108b can be made of a metal material such as aluminum, copper, titanium, tantalum, or tungsten. A stack of two or more layers of these materials may also be used. For example, as shown in FIG. 2B, the source or drain electrode 108a may be a stack of a conductive film 108a3, a conductive film 108a2, and a conductive film 108a1, and the drain or source electrode 108b may be a stack of a conductive film 108b3, a conductive film 108b2, and a conductive film 108b1.

The gate insulating film 104 can be made of a material similar to that of the first protective film 110 or the second protective film 112. Alternatively, a silicon nitride film, an aluminum oxide film, or the like may be used.

Further, a stack of two or more layers of these materials may be used. For example, as shown in FIG. 2C, the gate insulating film 104 may be a stack of an insulating film 104a and an insulating film 104b. In the case of using stacked films, the insulating film 104b in contact with the oxide semiconductor film 106 is preferably an insulating film from which oxygen is released by heat, for example, a silicon oxide film containing oxygen at a proportion exceeding the stoichiometric proportion. The insulating film 104a under the insulating film 104b is preferably a film with good coverage, for example, a silicon oxynitride film.

As shown in FIG. 2D, a channel-stop film 114a may be provided in contact with a part of the oxide semiconductor film 106. The channel-stop film 114a makes it possible to reduce contamination of the oxide semiconductor film 106 in a manufacturing process, resulting in an increase in the characteristics of the transistor 200. Further, channel-stop films 114a, 114b, and 114c may be provided as shown in FIG. 2E. The edges of the oxide semiconductor film 106 are covered with the channel-stop films 114b and 114c in FIG. 2E; thus, the contamination of the oxide semiconductor film 106 can be further reduced and the characteristics of the transistor 200 can be further increased. The channel-stop films 114a, 114b, and 114c can be made of a material similar to that of the gate insulating film 104.

The features of the structure of the semiconductor device including the transistor 200 shown in FIGS. 1A and 1B and FIGS. 2A to 2E may be used in combination.

The structure of the semiconductor device is not limited to that shown in FIGS. 1A and 1B and FIGS. 2A to 2E, where the first protective film 110 and the second protective film 112 are provided over the inverted-staggered (also referred to as bottom-gate) transistor 200. A similar effect can be obtained even if the components of the semiconductor device are stacked in reverse order. For example, in the case where the semiconductor device includes a staggered (top-gate) transistor, the second protective film 112 and the first protective film 110 can be provided under the transistor.

By using the silicon oxynitride film with high density for the protective film outward of the transistor, namely, the second protective film 112, entry of water into the semiconductor device can be sufficiently prevented.

Further, by using the insulating film from which oxygen is released by heat for the first protective film 110 in contact with the oxide semiconductor film 106, the density of oxygen vacancies can be reduced and a normally-off transistor can be easily obtained.

In the case of the semiconductor device including a staggered transistor, by providing the first protective film 110 and the second protective film 112 stacked under the transistor 200, a normally-off transistor with stable electric characteristics can be easily obtained.

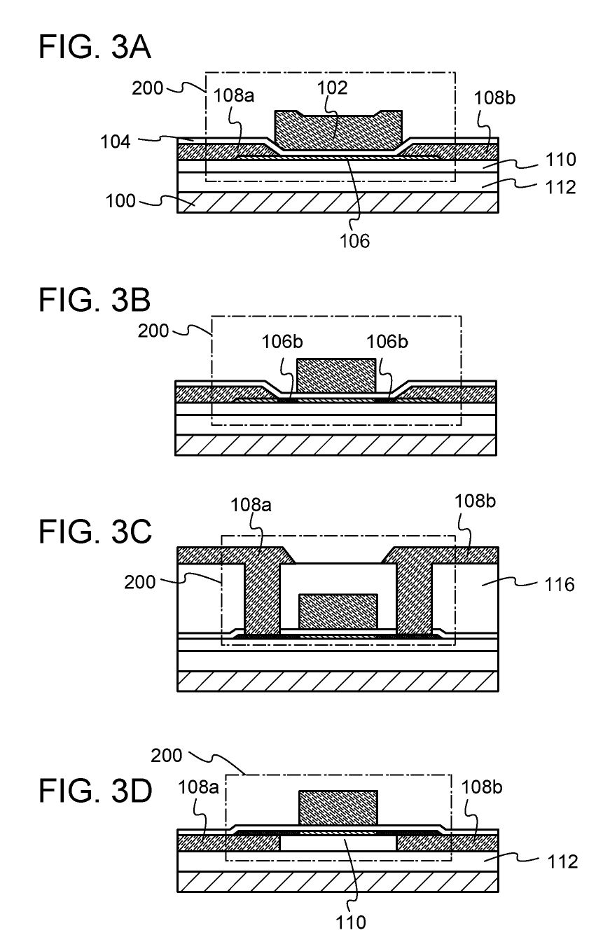

More specifically, the semiconductor device may have a structure shown in FIG. 3A: the second protective film 112 is provided over the substrate 100, the first protective film 110 is provided over the second protective film 112, and the staggered transistor 200 is provided over the first protective film 110. The transistor 200 includes the oxide semiconductor film 106 in contact with the first protective film 110; the source or drain electrode 108a and the drain or source electrode 108b in contact with the oxide semiconductor film 106; the gate electrode 102 over the oxide semiconductor film 106; and the gate insulating film 104 between the oxide semiconductor film 106 and the gate electrode 102.

A structure shown in FIG. 3B may also be used, where the gate electrode 102 does not overlap with the source or drain electrode 108a and the drain or source electrode 108b. Such a structure results in a reduction in the parasitic capacitance of the transistor 200. At this time, the oxide semiconductor film 106 preferably includes a pair of impurity regions 106b in regions which do not overlap with the gate electrode 102. The pair of impurity regions 106b can serve as LDD (lightly doped drain) regions, which makes it possible to prevent degradation of the characteristics of the transistor 200.

As an impurity added to the pair of impurity regions 106b, phosphorus, boron, nitrogen, carbon, argon, metal, or the like can be used.

As shown in FIG. 3C, the source or drain electrode 108a and the drain or source electrode 108b may be in contact with the oxide semiconductor film 106 through contact holes formed in the insulating film 116.

As shown in FIG. 3D, the source or drain electrode 108a and the drain or source electrode 108b may be in contact with the bottom surface of the oxide semiconductor film 106. The first protective film 110 needs to be in contact with only a channel region in the oxide semiconductor film 106 of the transistor 200. Therefore, the first protective film 110 does not necessarily overlap with the source or drain electrode 108a and the drain or source electrode 108b as shown in FIG. 3D.

### <Method for Manufacturing Semiconductor Device>

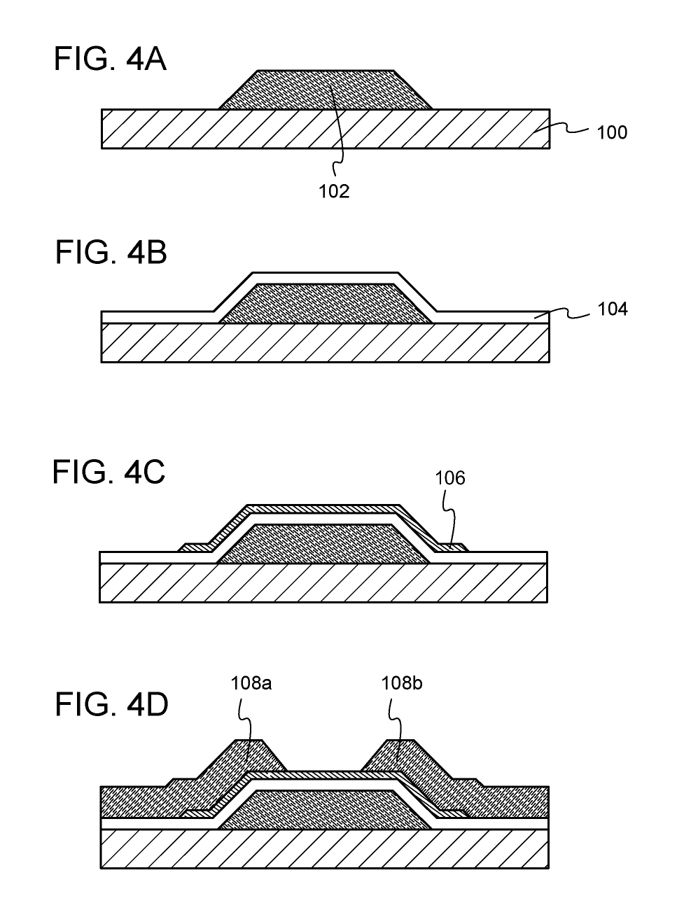

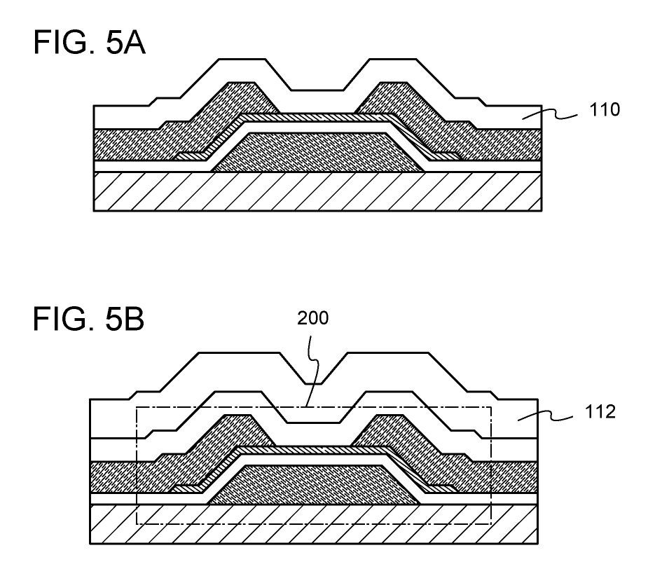

Next, a method for manufacturing the semiconductor device including the transistor 200 in FIGS. 1A and 1B will be described with reference to FIGS. 4A to 4D and FIGS. 5A and 5B.

First, a conductive film is formed over the substrate 100 by sputtering or the like, and processed by etching or the like so that the gate electrode 102 is formed (see FIG. 4A). As for the materials of the substrate 100 and the gate electrode 102, the description of FIGS. 1A and 1B can be referred to.

Then, a gate insulating film 104 is formed over the gate electrode 102 (see FIG. 4B). As for the material of the gate insulating film 104, the description of FIGS. 1A and 1B can be referred to.

The gate insulating film 104 can be formed by CVD such as PECVD or high-density plasma CVD, sputtering, or the like.

In the case of using CVD, a silicon oxide film can be formed using, for example, a SiH₄ gas. A silicon oxynitride film can be formed using, for example, a gas such as silane (SiH₄), nitrous oxide (N₂O), ammonia (NH₃), or nitrogen (N₂).

The gate insulating film 104 preferably includes a region in which the amount of oxygen is larger than the stoichiometric amount. In the case of a silicon oxide film whose composition is represented by SiOₓ (x>0), since silicon oxide has a stoichiometric ratio of Si:O=1:2, it is preferable to use a silicon oxide film which includes an oxygen excess region with a composition where x is greater than 2. Such an oxygen excess region needs to exist only in a part (including an interface) of the silicon oxide film.

The gate insulating film 104, which is in contact with the oxide semiconductor film 106 to be formed later, preferably includes a region in which the amount of oxygen is larger than the stoichiometric amount. This is because transfer of oxygen from the oxide semiconductor film 106 to the gate insulating film 104 in contact therewith can be prevented, and oxygen can also be supplied from the gate insulating film 104 in contact with the oxide semiconductor film 106 to the oxide semiconductor film 106.

Next, the substrate 100 over which the gate insulating film 104 is formed may be subjected to heat treatment for removing water, hydrogen, and the like.

The heat treatment can be performed using an electric furnace or a device for heating an object by heat conduction or heat radiation from a heating element such as a resistance heating element. For example, an RTA (rapid thermal anneal) apparatus such as an LRTA (lamp rapid thermal anneal) apparatus or a GRTA (gas rapid thermal anneal) apparatus can be used. The LRTA apparatus is an apparatus for heating an object by radiation of light (an electromagnetic wave) emitted from a lamp such as a halogen lamp, a metal halide lamp, a xenon arc lamp, a carbon arc lamp, a high-pressure sodium lamp, or a high-pressure mercury lamp. A GRTA apparatus is an apparatus for heat treatment using a high-temperature gas. As the high-temperature gas, an inert gas which does not react with an object by heat treatment, such as nitrogen or a rare gas like argon, is used.

For example, as the heat treatment, GRTA treatment may be performed as follows. An object is put in a heated inert gas atmosphere, heated for several minutes, and taken out of the inert gas atmosphere. The GRTA treatment enables high-temperature heat treatment in a short time. Further, the GRTA treatment can be performed even under the conditions of the temperature that exceeds the upper temperature limit of the object. Note that the inert gas may be changed to a gas containing oxygen during the process. This is because the defect density in the film can be reduced by performing the heat treatment in an atmosphere containing oxygen.

Note that as the inert gas atmosphere, an atmosphere that contains nitrogen or a rare gas (e.g., helium, neon, or argon) as its main component and does not contain water, hydrogen, or the like is preferably used. For example, the purity of nitrogen or a rare gas such as helium, neon, or argon introduced into a heat treatment apparatus is set to 6N (99.9999%) or more, preferably 7N (99.99999%) or more (i.e., the impurity concentration is 1 ppm or lower, preferably 0.1 ppm or lower).

In the case where the mother glass is used as the substrate 100, high process temperature and a long period of process time drastically shrink the mother glass; therefore, the temperature of the heat treatment is 200° C. to 450° C. inclusive, preferably 250° C. to 350° C. inclusive.

Impurities such as water or hydrogen in the gate insulating film 104 can be removed by the heat treatment. The defect density in the film can also be decreased by the heat treatment. Reduction in the impurities or defect density in the gate insulating film 104 leads to improvement in the reliability of the transistor. For example, it is possible to prevent deterioration of the transistor during a negative bias stress test with light irradiation, which is one of the reliability tests for semiconductor devices.

The above heat treatment can also be referred to as dehydration treatment, dehydrogenation treatment, or the like because of its advantageous effect of removing moisture, hydrogen, or the like. Such dehydration treatment or dehydrogenation treatment may be performed once or plural times.

Next, an oxide semiconductor film is formed and processed so that the oxide semiconductor film 106 is formed (see FIG. 4C).

As for the material of the oxide semiconductor film, the description of FIGS. 1A and 1B can be referred to. The oxide semiconductor film can be formed by sputtering, evaporation, CVD, PLD (pulse laser deposition), ALD (atomic layer deposition), MBE (molecular beam epitaxy), or the like.

The oxide semiconductor film is preferably formed by sputtering in an oxygen gas atmosphere at a substrate heating temperature of 100° C. to 600° C. inclusive, preferably 150° C. to 550° C. inclusive, and more preferably 200° C. to 500° C. inclusive. The thickness of the oxide semiconductor film is 1 nm to 50 nm inclusive, preferably 3 nm to 30 nm inclusive. As the substrate heating temperature in the deposition is higher, the impurity concentration of the obtained oxide semiconductor film is lower. Furthermore, the atomic arrangement in the oxide semiconductor film is ordered and the density thereof is increased, so that a polycrystalline oxide semiconductor film or a CAAC-OS film is likely to be formed. Furthermore, since an oxygen gas atmosphere is employed for the deposition, an unnecessary atom such as a rare gas atom is not contained in the oxide semiconductor film, so that a polycrystalline oxide semiconductor film or a CAAC-OS film is likely to be formed. Note that a mixed gas atmosphere including an oxygen gas and a rare gas may be used. In that case, the percentage of an oxygen gas is 30 at. % or more, preferably 50 at. % or more, and more preferably 80 at. % or more. As the oxide semiconductor film is thinner, the short channel effect of the transistor can be reduced. However, a too small thickness may increase the influence of the interface scattering and reduce the field-effect mobility.

In the case where the oxide semiconductor film is formed by sputtering using an In—Ga—Zn-based oxide, it is preferable to use an In—Ga—Zn-based target having an atomic ratio of In:Ga:Zn=1:1:1, 4:2:3, 3:1:2, 1:1:2, 2:1:3, or 3:1:4. After the heat treatment, the atomic ratio of Zn in the formed oxide semiconductor film becomes lower than that in the target in some cases. Therefore, it is also possible to use a target including Zn at an atomic ratio higher than a desired atomic ratio. When the oxide semiconductor film is formed using an In—Ga—Zn-based target having the aforementioned atomic ratio, a polycrystalline oxide semiconductor film or a CAAC-OS film is likely to be formed.

In the case where the oxide semiconductor film is formed by sputtering using an In—Sn—Zn-based oxide, it is preferable to use an In—Sn—Zn-based target having an atomic ratio of In:Sn:Zn=1:1:1, 2:1:3, 1:2:2, or 20:45:35. It is also possible to use a target including Zn at an atomic ratio higher than a desired atomic ratio. When the oxide semiconductor film is formed using an In—Sn—Zn-based target having the aforementioned atomic ratio, a polycrystalline oxide semiconductor film or a CAAC-OS film is likely to be formed.

In order to form the CAAC-OS film with higher quality, the following conditions are preferably applied.

First, the CAAC-OS film is preferably formed by sputtering using a polycrystalline oxide semiconductor sputtering target.

When ions collide with the polycrystalline oxide semiconductor sputtering target, a crystal region included in the sputtering target may be separated from the target along an a-b plane; in other words, a sputtered particle having a plane parallel to an a-b plane (flat-plate-like sputtered particle or pellet-like sputtered particle) may flake off from the sputtering target. In that case, the flat-plate-like sputtered particle reaches a substrate while keeping its crystal state, whereby the crystal state of the sputtering target is transferred to the substrate and the CAAC-OS film can be formed.

For example, an In—Ga—Zn—O-based oxide semiconductor sputtering target, which is polycrystalline, is produced by mixing InO_{X} powder, GaO_{Y} powder, and ZnO_{Z} powder in a predetermined ratio, applying pressure, and performing heat treatment at a temperature of 1000° C. to 1500° C. inclusive. Note that X, Y and Z are given positive numbers. A polycrystalline sputtering target including another element can also be similarly produced.

Then, the concentration of impurities in the deposition is preferably reduced so as to prevent the crystal state from being broken by the impurities.

For example, the concentration of impurities (e.g., hydrogen, water, carbon dioxide, or nitrogen) which exist in the deposition chamber may be reduced. Furthermore, the concentration of impurities in a deposition gas may be reduced. Specifically, a deposition gas whose dew point is −80° C. or lower, preferably −100° C. or lower is used.

By increasing the substrate heating temperature during the deposition, migration of a sputtered particle is likely to occur after the sputtered particle is attached to a substrate surface. Specifically, the substrate heating temperature during the deposition is 100° C. to 740° C. inclusive, preferably 200° C. to 500° C. inclusive. By increasing the substrate heating temperature during the deposition, when the flat-plate-like sputtered particle reaches the substrate, migration occurs on the substrate surface, so that a flat plane of the flat-plate-like sputtered particle is attached to the substrate.

Furthermore, it is preferable that the proportion of oxygen in the deposition gas be increased and the power be optimized in order to reduce plasma damage at the deposition. The proportion of oxygen in the deposition gas is 30 volume % or higher, preferably 100 volume %.

Next, heat treatment is preferably performed. The heat treatment is performed in a reduced pressure atmosphere, an inert atmosphere, or an oxidizing atmosphere. By the heat treatment, the concentration of impurities in the oxide semiconductor film can be reduced.

It is preferable that the heat treatment be performed in a reduced pressure atmosphere or an inert atmosphere first and then further performed while the atmosphere is switched to an oxidizing atmosphere with the temperature maintained. When the heat treatment is performed in a reduced pressure atmosphere or an inert atmosphere, the impurity concentration in the oxide semiconductor can be reduced; however, oxygen vacancies are caused at the same time. The caused oxygen vacancies can be reduced by the heat treatment in the oxidizing atmosphere.

The oxidizing atmosphere is an atmosphere containing an oxidizing gas. Oxidizing gas is oxygen, ozone, nitrous oxide, or the like, and it is preferable that the oxidizing gas do not contain water, hydrogen, and the like. For example, the purity of oxygen, ozone, or nitrous oxide to be introduced into a heat treatment apparatus is 8N (99.999999%) or more, preferably 9N (99.9999999%) or more. As the oxidizing atmosphere, an oxidizing gas and an inert gas may be mixed to be used. In that case, the mixture contains an oxidizing gas at a concentration of 10 ppm or more.

The inert atmosphere refers to an atmosphere containing an inert gas (such as nitrogen or a rare gas (e.g., helium, neon, argon, krypton, or xenon)) as the main component. Specifically, the concentration of a reactive gas such as an oxidizing gas is lower than 10 ppm.

The impurity level in the oxide semiconductor film can be significantly reduced by performing the heat treatment after the deposition in addition to the substrate heating in the deposition.

The heat treatment makes it possible to increase the proportion of a crystal region with respect to an amorphous region in the oxide semiconductor film. The heat treatment may be performed at a temperature of higher than or equal to 200° C. and lower than the strain point of the substrate, and is preferably performed at a temperature of 250° C. to 450° C. inclusive. The heat treatment is preferably performed in an oxidizing atmosphere, an inert atmosphere, or a reduced pressure atmosphere (10 Pa or less). The treatment time is 3 minutes to 24 hours. The treatment for longer time increases the proportion of a crystal region with respect to an amorphous region in the oxide semiconductor film; however, heat treatment for longer than 24 hours is not preferable because it decreases the productivity.

The oxide semiconductor film is processed by etching or the like, whereby the island-like oxide semiconductor film 106 is obtained.

Then, a conductive film is formed over the oxide semiconductor film 106 and then processed so that the source or drain electrode 108a and the drain or source electrode 108b are formed (see FIG. 4D).

As for the materials and manufacturing methods of the source or drain electrode 108a and the drain or source electrode 108b, the description of FIGS. 1A and 1B and the description of the gate electrode 102 can be referred to.

Next, the first protective film 110 is formed over the oxide semiconductor film 106, the source or drain electrode 108a, and the drain or source electrode 108b (see FIG. 5A).

As for the material of the first protective film 110, the description of FIGS. 1A and 1B can be referred to. The first protective film 110 can be formed by PECVD, sputtering, or the like. It is particularly preferable that the first protective film 110 be formed by sputtering so as to obtain an insulating film containing oxygen at a proportion exceeding the stoichiometric proportion.

Then, the second protective film 112 is formed over the first protective film 110 (see FIG. 5B).

As for the material of the second protective film 112, the description of FIGS. 1A and 1B can be referred to. The second protective film 112 can be formed by PECVD, sputtering, or the like. It is particularly preferable that the second protective film 112 be formed by CVD so that a silicon oxynitride film with high density can be obtained with high productivity. The thickness of the second protective film 112 is preferably 500 nm to 700 nm inclusive so that the amount of water entering the semiconductor device can be sufficiently reduced and the second protective film 112 can be obtained with high productivity.

In the case where the second protective film 112 is formed by PECVD, a silicon oxynitride film with high density can be obtained when the flow rate ratio of silane to nitrous oxide (SiH₄/N₂O) is 0.01 or less. It is preferable that the flow rate ratio SiH₄/N₂O be 0.0066 or more because high productivity is achieved. Further, a silicon oxynitride film with high density can also be obtained by increasing power. For example, with a power of 1000 W, a silicon oxynitride film with high density can be formed even when the flow rate ratio SiH₄/N₂O is 0.01 or more.

In such a manner, the amount of water entering the semiconductor device using an oxide semiconductor can be reduced, which makes it possible to manufacture the semiconductor device including the transistor 200 with a smaller variation in characteristics.

### Embodiment 2

A semiconductor device with a display function (also referred to as a display device) can be manufactured using the transistor described in Embodiment 1.

Moreover, some or all of the driver circuits which include the transistor can be formed over a substrate where the pixel portion is formed, whereby a system-on-panel can be obtained.

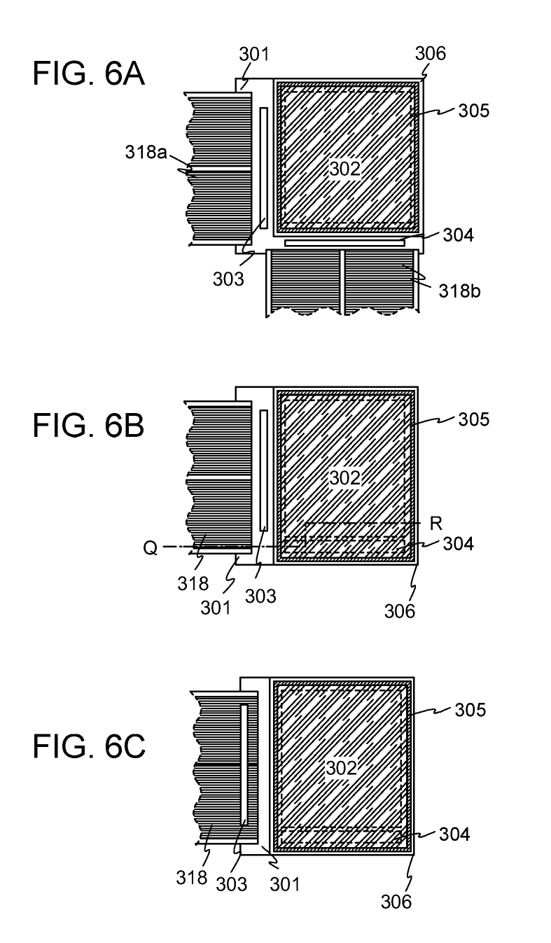

In FIG. 6A, a sealant 305 is provided to surround a pixel portion 302 provided over a first substrate 301, and the pixel portion 302 is sealed with the sealant 305 and the second substrate 306. In FIG. 6A, a scan line driver circuit 304 and a signal line driver circuit 303 each are formed using a single crystal semiconductor film or a polycrystalline semiconductor film over a substrate prepared separately, and mounted in a region different from the region surrounded by the sealant 305 over the first substrate 301. A variety of signals and potentials are supplied from flexible printed circuits (FPCs) 318a and 318b to the pixel portion 302, and the signal line driver circuit 303 and the scan line driver circuit 304 which are provided separately.

In FIGS. 6B and 6C, the sealant 305 is provided to surround the pixel portion 302 and the scan line driver circuit 304 which are provided over the first substrate 301. The second substrate 306 is provided over the pixel portion 302 and the scan line driver circuit 304. Consequently, the pixel portion 302 and the scan line driver circuit 304 are sealed together with the display element, by the first substrate 301, the sealant 305, and the second substrate 306. In FIGS. 6B and 6C, the signal line driver circuit 303 is formed using a single crystal semiconductor film or a polycrystalline semiconductor film over a substrate prepared separately, and mounted in a region different from the region surrounded by the sealant 305 over the first substrate 301. In FIGS. 6B and 6C, a variety of signals and potentials are supplied from an FPC 318 to the signal line driver circuit 303 provided separately, and the scan line driver circuit 304 or the pixel portion 302.

Although FIGS. 6B and 6C each show an example in which the signal line driver circuit 303 is formed separately and mounted on the first substrate 301, one embodiment of the present invention is not limited to this structure. The scan line driver circuit may be formed separately and then mounted, or only part of the signal line driver circuit or part of the scan line driver circuit may be formed separately and then mounted.

Note that a connection method of a separately formed driver circuit is not particularly limited, and a chip on glass (COG) method, a wire bonding method, a tape automated bonding (TAB) method or the like can be used. FIG. 6A shows an example in which the signal line driver circuit 303 and the scan line driver circuit 304 are mounted by a COG method. FIG. 6B shows an example in which the signal line driver circuit 303 is mounted by a COG method. FIG. 6C illustrates an example in which the signal line driver circuit 303 is mounted by a TAB method.

Note that the display device includes a panel in which the display element is sealed, and a module in which an IC including a controller or the like is mounted on the panel.

A display device in this specification means an image display device, a display device, or a light source (including a lighting device). Furthermore, the display device also includes the following modules in its category: a module to which a connector such as an FPC, a TAB tape, or a TCP is attached; a module having a TAB tape or a TCP at the tip of which a printed wiring board is provided; and a module in which an integrated circuit (IC) is directly mounted on a display element by a COG method.

The pixel portion 302 and the scan line driver circuit 304 which are provided over the first substrate 301 include a plurality of transistors and the transistor described in Embodiment 1 can be used.

As the display element provided in the display device, a liquid crystal element (also referred to as a liquid crystal display element) or a light-emitting element (also referred to as a light-emitting display element) can be used. The light-emitting element includes, in its category, an element whose luminance is controlled by a current or a voltage, and specifically includes, in its category, an inorganic electroluminescent (EL) element, an organic EL element, and the like. Furthermore, a display medium whose contrast is changed by an electric effect, such as electronic ink, can be used.

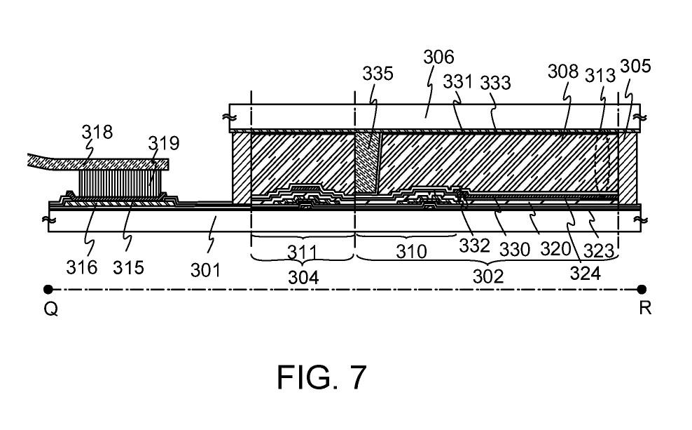

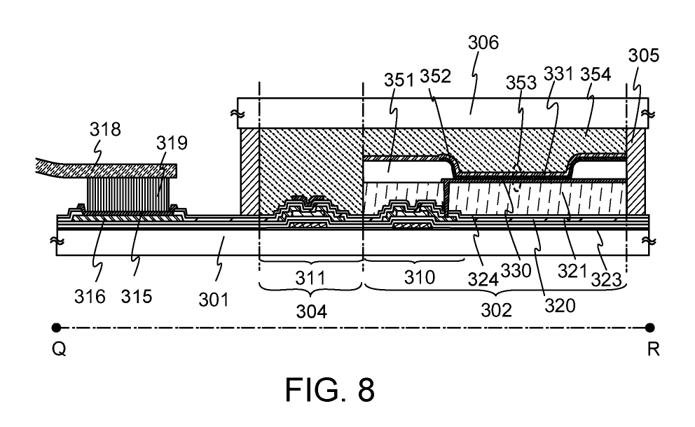

Embodiments of the semiconductor device will be described with reference to FIG. 7 and FIG. 8. FIG. 7 and FIG. 8 are cross-sectional views along line Q-R in FIG. 6B.

As shown in FIG. 7 and FIG. 8, the semiconductor device includes a connection terminal electrode film 315 and a terminal electrode film 316. The connection terminal electrode film 315 and the terminal electrode film 316 are electrically connected to a terminal included in the FPC 318 through an anisotropic conductive film 319.

The connection terminal electrode film 315 is formed using the same conductive film as a first electrode film 330. The terminal electrode film 316 is formed using the same conductive film as source and drain electrode films of transistors 310 and 311.

Each of the pixel portion 302 and the scan line driver circuit 304 which are provided over the first substrate 301 includes a plurality of transistors. In FIG. 7 and FIG. 8, the transistor 310 included in the pixel portion 302 and the transistor 311 included in the scan line driver circuit 304 are illustrated as an example. In FIG. 7, a protective film 320 and a protective film 324 are provided over the transistors 310 and 311, and an insulating film 321 is further provided in FIG. 8. Note that an insulating film 323 serves as a base film.

In this embodiment, the transistor described in Embodiment 1 can be applied to the transistor 310 and the transistor 311.

The transistor 310 and the transistor 311 are each a transistor including an oxide semiconductor film in which formation of an oxygen vacancy and entry of water or hydrogen are prevented. Therefore, a variation in the electric characteristics of the transistors 310 and 311 is prevented, and the transistors 310 and 311 are electrically stable.

Thus, highly reliable semiconductor devices can be provided as the semiconductor devices of this embodiment illustrated in FIG. 7 and FIG. 8.

The transistor 310 included in the pixel portion 302 is electrically connected to a display element to form a display panel. There is no particular limitation on the kind of the display element as long as display can be performed, and a variety of kinds of display elements can be employed.

FIG. 7 illustrates an example of a liquid crystal display device using a liquid crystal element as a display element. In FIG. 7, a liquid crystal element 313 as a display element includes the first electrode film 330, a second electrode film 331, and a liquid crystal layer 308. An insulating film 332 and an insulating film 333 serving as alignment films are provided so that the liquid crystal layer 308 is interposed therebetween. The second electrode film 331 is provided on the second substrate 306 side, and the first electrode film 330 and the second electrode film 331 are stacked with the liquid crystal layer 308 interposed therebetween.

A columnar spacer 335, which is obtained by selective etching of an insulating film, is provided in order to control the thickness (cell gap) of the liquid crystal layer 308. Alternatively, a spherical spacer may be used.

In the case where a liquid crystal element is used as the display element, a thermotropic liquid crystal, a low-molecular liquid crystal, a high-molecular liquid crystal, a polymer dispersed liquid crystal, a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

Alternatively, a liquid crystal exhibiting a blue phase for which an alignment film is unnecessary may be used. A blue phase is one of the liquid crystal phases, which appears just before a cholesteric phase changes into an isotropic phase while the temperature of a cholesteric liquid crystal is increased. Since the blue phase appears only in a narrow temperature range, a liquid crystal composition in which several weight percent or more of a chiral agent is mixed is used for the liquid crystal layer in order to improve the temperature range. The liquid crystal composition which includes a liquid crystal exhibiting a blue phase and a chiral agent has a short response time, and has optical isotropy, which contributes to the exclusion of the alignment process and reduction of viewing angle dependence. In addition, since an alignment film does not need to be provided and rubbing treatment is unnecessary, electrostatic discharge damage caused by the rubbing treatment can be prevented and defects and damage of the liquid crystal display device in the manufacturing process can be reduced. Thus, productivity of the liquid crystal display device can be improved. A transistor formed using an oxide semiconductor film has a possibility that the electric characteristics of the transistor may fluctuate significantly by the influence of static electricity and deviate from the designed range. Therefore, it is more effective to use a liquid crystal material exhibiting a blue phase for the liquid crystal display device including the transistor formed using an oxide semiconductor film.

The specific resistivity of the liquid crystal material is 1×10⁹ Ω·cm or more, preferably 1×10¹¹ Ω·cm or more, and further preferably 1×10¹² Ω·cm or more. Note that the specific resistivity in this specification is measured at 20° C.

The size of a storage capacitor formed in the liquid crystal display device is set considering, for example, the leakage current of the transistor provided in the pixel portion so that charge can be held for a predetermined period. The size of the storage capacitor may be set considering, for example, the off-state current of the transistor. By using a transistor which includes an oxide semiconductor film having an oxygen-excess region, it is enough to provide a storage capacitor having a capacitance that is ⅓ or less, preferably ⅕ or less, of liquid crystal capacitance of each pixel.

In the transistor used in this embodiment, which includes an oxide semiconductor film in which formation of an oxygen vacancy is prevented, the current in an off state (off-state current) can be made small. Accordingly, an electric signal such as an image signal can be held for a longer period, and a writing interval can be set longer in an on state. Accordingly, the frequency of refresh operation can be reduced, which leads to an effect of suppressing power consumption.

The transistor used in this embodiment, which includes an oxide semiconductor film in which formation of an oxygen vacancy is prevented, can have relatively high field-effect mobility and thus can operate at high speed. For example, when such a transistor which can operate at high speed is used for a liquid crystal display device, a switching transistor in a pixel portion and a driver transistor in a driver circuit portion can be formed over one substrate. That is, since a semiconductor device formed of a silicon wafer or the like is not additionally needed as a driver circuit, the number of components of the semiconductor device can be reduced. In addition, by using a transistor which can operate at high speed in a pixel portion, a high-quality image can be provided.

For the liquid crystal display device, a twisted nematic (TN) mode, an in-plane-switching (IPS) mode, a fringe field switching (FFS) mode, an axially symmetric aligned micro-cell (ASM) mode, an optical compensated birefringence (OCB) mode, a ferroelectric liquid crystal (FLC) mode, an anti-ferroelectric liquid crystal (AFLC) mode, or the like can be used.

A normally black liquid crystal display device such as a transmissive liquid crystal display device utilizing a vertical alignment (VA) mode may be used. Some examples are given as the vertical alignment mode. For example, a multi-domain vertical alignment (MVA) mode, a patterned vertical alignment (PVA) mode, or an advanced super view (ASV) mode can be used. Furthermore, this embodiment can be applied to a VA liquid crystal display device. The VA liquid crystal display device has a kind of form in which alignment of liquid crystal molecules of a liquid crystal display panel is controlled. In the VA liquid crystal display device, liquid crystal molecules are aligned in a vertical direction with respect to a panel surface when no voltage is applied. Moreover, it is possible to use a method called domain multiplication or multi-domain design, in which a pixel is divided into some regions (subpixels) and molecules are aligned in different directions in their respective regions.

In the display device, a black matrix (light-blocking layer), an optical member (optical substrate) such as a polarizing member, a retardation member, or an anti-reflection member, and the like are provided as appropriate. For example, circular polarization may be obtained by using a polarizing substrate and a retardation substrate. In addition, a backlight, a side light, or the like may be used as a light source.

As a display method in the pixel portion, a progressive method, an interlace method, or the like can be employed. Further, color elements controlled in a pixel at the time of color display are not limited to three colors: R, G, and B (R, G, and B correspond to red, green, and blue, respectively). For example, R, G, B, and W (W corresponds to white); R, G, B, and one or more of yellow, cyan, magenta, and the like; or the like can be used. Further, the sizes of display regions may be different between respective dots of color elements. Note that one embodiment of the disclosed invention is not limited to the application to a display device for color display; one embodiment of the disclosed invention can also be applied to a display device for monochrome display.

Alternatively, as the display element included in the display device, a light-emitting element utilizing electroluminescence can be used. Light-emitting elements utilizing electroluminescence are classified according to whether a light-emitting material is an organic compound or an inorganic compound. In general, the former is referred to as organic EL element, and the latter is referred to as inorganic EL element.

In an organic EL element, by application of voltage to a light-emitting element, electrons and holes are separately injected from a pair of electrodes into a layer containing a light-emitting organic compound, and current flows. The carriers (electrons and holes) are recombined, and thus the light-emitting organic compound is excited. The light-emitting organic compound returns to a ground state from the excited state, thereby emitting light. Owing to such a mechanism, this light-emitting element is referred to as current-excitation light-emitting element.

Inorganic EL elements are classified according to their element structures into a dispersion-type inorganic EL element and a thin-film inorganic EL element. A dispersion-type inorganic EL element has a light-emitting layer where particles of a light-emitting material are dispersed in a binder, and its light emission mechanism is donor-acceptor recombination type light emission that utilizes a donor level and an acceptor level. A thin-film inorganic EL element has a structure where a light-emitting layer is interposed between dielectric layers, which are further interposed between electrodes, and its light emission mechanism is localized type light emission that utilizes inner-shell electron transition of metal ions. Note that an example of an organic EL element is described here as a light-emitting element.

In order to extract light emitted from the light-emitting element, at least one of the pair of electrodes has a light-transmitting property. A transistor and a light-emitting element are formed over a substrate. The light-emitting element can have a top emission structure in which light emission is extracted through a surface opposite to the substrate; a bottom emission structure in which light emission is extracted through a surface on the substrate side; or a dual emission structure in which light emission is extracted through the surface opposite to the substrate and the surface on the substrate side, and a light-emitting element having any of these emission structures can be used.

FIG. 8 shows an example of a light-emitting device including a light-emitting element as a display element. A light-emitting element 353 which is a display element is electrically connected to the transistor 310 provided in the pixel portion 302. A structure of the light-emitting element 353 is not limited to the illustrated stacked structure including the first electrode film 330, an electroluminescent layer 352, and the second electrode film 331. The structure of the light-emitting element 353 can be changed as appropriate depending on, for example, the direction in which light is extracted from the light-emitting element 353.

A partition wall 351 is made of an organic insulating material or an inorganic insulating material. It is particularly preferable that the partition wall 351 be made of a photosensitive resin material to have an opening over the first electrode film 330 so that a sidewall of the opening is formed as a tilted surface with continuous curvature.

The electroluminescent layer 352 may be formed using either a single layer or a plurality of layers stacked.

A protective film may be formed over the second electrode film 331 and the partition wall 351 in order to prevent entry of oxygen, hydrogen, moisture, carbon dioxide, or the like into the light-emitting element 353. As the protective film, a silicon nitride film, a silicon nitride oxide film, a diamond-like carbon (DLC) film, or the like can be formed. In addition, in a space which is formed with the first substrate 301, the second substrate 306, and the sealant 305, a filler 354 is provided for sealing. In this manner, the light-emitting element 353 and the like are preferably packaged (sealed) with a protective film (such as a laminate film or an ultraviolet curable resin film) or a cover material with high air-tightness and little degasification so that the light-emitting element 353 and the like are not exposed to the outside air.

As the filler 354, an ultraviolet curable resin or a thermosetting resin can be used as well as an inert gas such as nitrogen or argon. For example, polyvinyl chloride (PVC), acrylic, polyimide, an epoxy resin, a silicone resin, polyvinyl butyral (PVB), or ethylene vinyl acetate (EVA) can be used. For example, nitrogen is used as the filler.

If necessary, an optical film such as a polarizing plate, a circularly polarizing plate (including an elliptically polarizing plate), a retardation plate (a quarter-wave plate or a half-wave plate), or a color filter may be provided as appropriate on a light-emitting surface of the light-emitting element. Further, the polarizing plate or the circularly polarizing plate may be provided with an anti-reflection film. For example, it is possible to perform anti-glare treatment by which reflected light can be diffused by projections and depressions on the surface so as to reduce the glare.

Note that in FIG. 7 and FIG. 8, a flexible substrate as well as a glass substrate can be used as the first substrate 301 and the second substrate 306. For example, a plastic substrate having a light-transmitting property can be used. As plastic, a fiberglass-reinforced plastics (FRP) plate, a polyvinyl fluoride (PVF) film, a polyester film, or an acrylic resin film can be used. Alternatively, a sheet with a structure in which an aluminum foil is interposed between PVF films or polyester films can be used.

In this embodiment, a silicon oxide film is used as the protective film 320, and a silicon oxynitride film is used as the protective film 324. The protective film 320 and the protective film 324 can be formed by sputtering or plasma CVD.

The silicon oxynitride film provided as the protective film 324 over the oxide semiconductor film preferably has a density of 2.32 g/cm³ or more, preferably 2.36 g/cm³ or more, which leads to a high shielding effect (blocking effect) of preventing penetration of both oxygen and impurities such as hydrogen and moisture.

Therefore, in and after the manufacturing process, the silicon oxynitride film functions as a protective film for preventing entry of impurities such as hydrogen or moisture, which cause a change in characteristics, into the oxide semiconductor film and release of oxygen, which is a main component material of the oxide semiconductor film, from the oxide semiconductor film.

The silicon oxide film provided as the protective film 320 in contact with the oxide semiconductor film has a function of supplying oxygen to the oxide semiconductor film. Therefore, the protective film 320 is preferably an oxide insulating film containing much oxygen.

The transistor 310 and the transistor 311 each include an oxide semiconductor film which is highly purified and in which formation of an oxygen vacancy is prevented. In the transistor 310 and the transistor 311, a gate insulating film is formed using a silicon nitride oxide film, a silicon oxynitride film, and a metal oxide film. With such a structure of the gate insulating film, a variation in characteristics is prevented and the transistors are electrically stable.

The insulating film 321 serving as a planarization insulating film can be made of an organic material having heat resistance, such as acrylic, polyimide, benzocyclobutene, polyamide, or epoxy. The insulating film may be formed by stacking a plurality of insulating films made of these materials.

There is no particular limitation on the method for forming the insulating film 321, and the following method or tool (equipment) can be used depending on the material: a sputtering method, an SOG method, spin coating, dipping, spray coating, a droplet discharge method (such as an inkjet method), a printing method (such as screen printing or offset printing), a doctor knife, a roll coater, a curtain coater, a knife coater, or the like.

The display device displays an image by transmitting light from a light source or a display element. Therefore, the substrate and the thin films such as the insulating film and the conductive film provided for the pixel portion where light is transmitted have light-transmitting properties with respect to light in the visible light wavelength range.

The first electrode film and the second electrode film (also referred to as a pixel electrode film, a common electrode film, a counter electrode film, or the like) for applying voltage to the display element may have light-transmitting properties or light-reflecting properties, which depends on the direction in which light is extracted, the position where the electrode film is provided, the pattern structure of the electrode film, and the like.

The first electrode film 330 and the second electrode film 331 can be formed using a light-transmitting conductive material such as indium oxide containing tungsten oxide, indium zinc oxide containing tungsten oxide, indium oxide containing titanium oxide, indium tin oxide containing titanium oxide, indium tin oxide, indium zinc oxide, indium tin oxide to which silicon oxide is added, or graphene.

The first electrode film 330 and the second electrode film 331 can be formed using one or plural kinds selected from metals such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag); an alloy thereof; and a nitride thereof.

A conductive composition containing a conductive high molecule (also referred to as conductive polymer) can be used for the first electrode film 330 and the second electrode film 331. As the conductive high molecule, a so-called π-electron conjugated conductive polymer can be used. For example, polyaniline or a derivative thereof, polypyrrole or a derivative thereof, polythiophene or a derivative thereof, a copolymer of two or more of aniline, pyrrole, and thiophene or a derivative thereof can be given.

Since the transistor is easily broken owing to static electricity or the like, a protection circuit for protecting the driver circuit is preferably provided. The protection circuit is preferably formed using a nonlinear element.

By thus using the transistor described in the above embodiment, the semiconductor device having a variety of functions can be provided.

As described above, by forming the silicon oxynitride film with a density of 2.32 g (cm³ or more, preferably 2.36 g/cm³ or more, penetration and diffusion of moisture or hydrogen from the atmosphere in the oxide semiconductor film can be prevented in the semiconductor device realizing a display function with use of the transistor. Thus, a variation in the electric characteristics of the transistor is prevented, and the transistor is electrically stable. Accordingly, a highly reliable semiconductor device can be provided by using the transistor.

This embodiment can be implemented in appropriate combination with the other embodiments.

### Embodiment 3

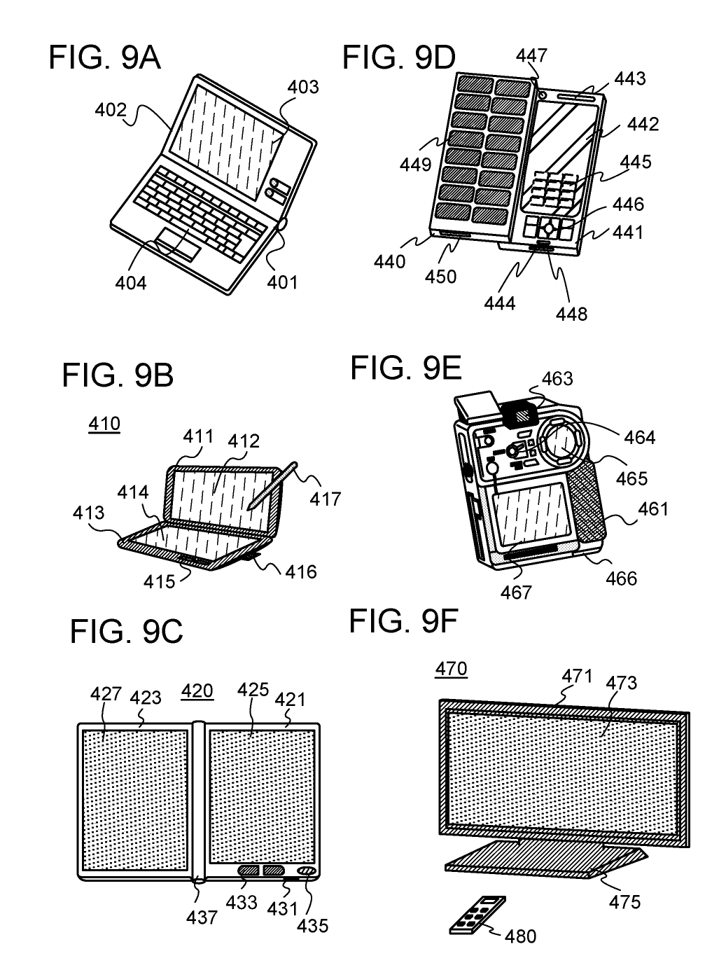

In this embodiment, the case where the semiconductor device described in the above embodiments is applied to an electronic apparatus will be described with reference to FIGS. 9A to 9F. Described in this embodiment is the case where the aforementioned semiconductor device is applied to electronic apparatuses such as a computer, a cellular phone handset (also referred to as a cellular phone or a cellular phone device), a personal digital assistant (including a portable game machine, an audio reproducing device, and the like), a camera such as a digital camera or a digital video camera, electronic paper, and a television set (also referred to as a television or a television receiver).

FIG. 9A is a laptop, which includes a housing 401, a housing 402, a display portion 403, a keyboard 404, and the like. At least one of the housings 401 and 402 includes an electronic circuit and the semiconductor device in the above embodiments is provided in the electronic circuit. Thus, a laptop with sufficiently low power consumption, in which data is calculated, written, and read at high speed, can be obtained.

FIG. 9B is a tablet terminal 410. The tablet terminal 410 includes a housing 411 having a display portion 412, a housing 413 having a display portion 414, operation keys 415, and an external interface 416. In addition, a stylus 417 for operating the tablet terminal 410, and the like are provided. At least one of the housings 411 and 413 includes an electronic circuit and the semiconductor device in the above embodiments is provided in the electronic circuit. Accordingly, a tablet terminal with sufficiently low power consumption, in which data is calculated, written, and read at high speed, can be obtained.

FIG. 9C is an e-book reader 420 incorporating electronic paper, which includes two housings, a housing 421 and a housing 423. The housing 421 and the housing 423 include a display portion 425 and a display portion 427, respectively. The housing 421 and the housing 423 are connected by a hinge 437 and can be opened and closed along the hinge 437. The housing 421 further includes a power switch 431, operation keys 433, a speaker 435, and the like. At least one of the housings 421 and 423 includes a memory circuit and the semiconductor device in the above embodiments is provided in the memory circuit. Accordingly, an e-book reader with sufficiently low power consumption, in which data is written and read at high speed, can be obtained.

FIG. 9D is a cellular phone including two housings, a housing 440 and a housing 441. Moreover, the housing 440 and the housing 441 which are developed as illustrated in FIG. 9D can be slid so that one is lapped over the other, which allows the cellular phone to be reduced in size and carried easily. The housing 441 includes a display panel 442, a speaker 443, a microphone 444, operation keys 445, a pointing device 446, a camera lens 447, an external connection terminal 448, and the like. The housing 440 includes a solar cell 449 for charging the cellular phone, an external memory slot 450, and the like. Further, an antenna is incorporated in the housing 441. At least one of the housings 440 and 441 includes an electronic circuit and the semiconductor device in the above embodiments is provided in the electronic circuit. Accordingly, a cellular phone with sufficiently low power consumption, in which data is calculated, written, and read at high speed, can be obtained.

FIG. 9E is a digital camera including a main body 461, a display portion 467, an eyepiece 463, an operation switch 464, a display portion 465, a battery 466, and the like. The main body 461 includes an electronic circuit and the semiconductor device in the above embodiments is provided in the electronic circuit. Accordingly, a digital camera with sufficiently low power consumption, in which data is calculated, written, and read at high speed, can be obtained.

FIG. 9F is a television set 470 including a housing 471, a display portion 473, a stand 475, and the like. The television set 470 can be operated with an operation switch of the housing 471 or a remote controller 480. The housing 471 and the remote controller 480 include an electronic circuit and the semiconductor device in the above embodiments is provided in the electronic circuit. Accordingly, a television set with sufficiently low power consumption, in which data is calculated, written, and read at high speed, can be obtained.

As described above, the semiconductor device in the above embodiments is mounted on each of the electronic apparatuses shown in this embodiment. Therefore, electronic apparatuses with low power consumption are realized.

In the following examples, various kinds of silicon oxynitride films are practically formed by PECVD, and the evaluation results of the silicon oxynitride films will be shown. Further, transistors using the silicon oxynitride films as protective films are formed, and the evaluation results of the transistors will be shown.

### Example 1

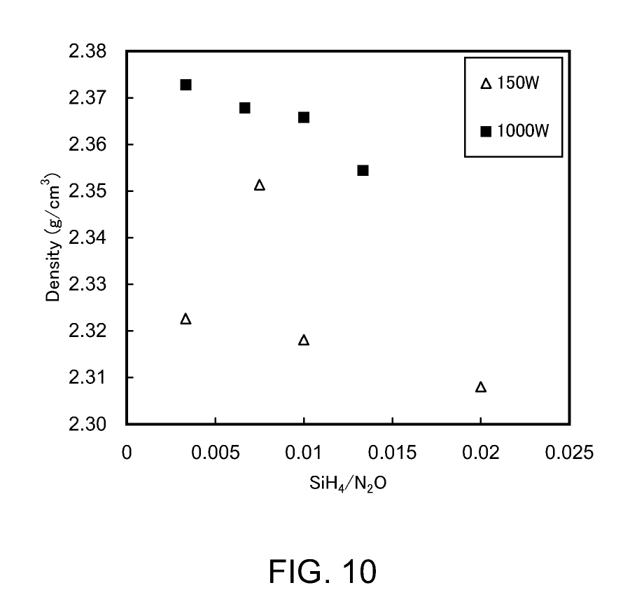

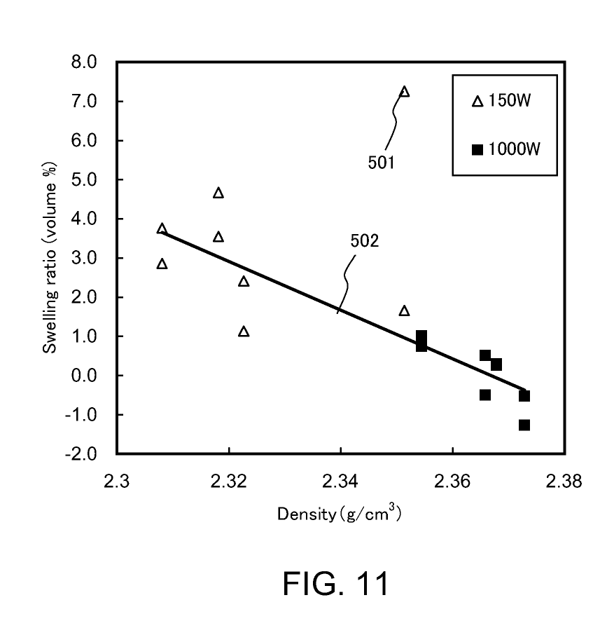

In this example, various kinds of silicon oxynitride films were formed. The results of measuring the density and swelling ratio of the silicon oxynitride films will be shown with reference to FIG. 10 and FIG. 11.

In this example, various kinds of silicon oxynitride films were formed over a glass substrate by PECVD using silane (SiH₄) and nitrous oxide (N₂O). The flow rate ratio of silane to nitrous oxide (SiH₄/N₂O) and the conditions of power were mainly changed.

The density of the silicon oxynitride films was measured using XRR. In addition, the thicknesses of the silicon oxynitride films before and after the PCT and the HAST were measured so that the swelling ratio was calculated.

The PCT and the HAST were performed under the following conditions.

PCT: temperature, 130° C.; relative humidity, 100%; test time, 12 hours
HAST: temperature, 130° C.; relative humidity, 85%; test time, 12 hours

Table 1 shows specific conditions of deposition of the silicon oxynitride films, and the results of density and swelling ratio.

TABLE 1

| | | | Pres- | | | Swelling | |
|---|---|---|---|---|---|---|---|
| SiH₄ | N₂O | SiH₄/ | sure | RF | | ratio | Density |
| [sccm] | [sccm] | N₂O | [Pa] | [W] | Test | [volume %] | [g/cm³] |
| 30 | 9000 | 0.003 | 80 | 150 | PCT | 2.41 | 2.323 |
| 90 | 9000 | 0.010 | 80 | 150 | PCT | 4.67 | 2.318 |
| 60 | 3000 | 0.020 | 80 | 150 | PCT | 3.77 | 2.308 |
| 30 | 4000 | 0.008 | 200 | 150 | PCT | 1.66 | 2.351 |
| 30 | 9000 | 0.003 | 80 | 150 | HAST | 1.13 | 2.323 |
| 90 | 9000 | 0.010 | 80 | 150 | HAST | 3.55 | 2.318 |
| 60 | 3000 | 0.020 | 80 | 150 | HAST | 2.86 | 2.308 |
| 30 | 4000 | 0.008 | 200 | 150 | HAST | 7.26 | 2.351 |
| 30 | 9000 | 0.003 | 80 | 1000 | PCT | −1.27 | 2.373 |
| 60 | 9000 | 0.007 | 80 | 1000 | PCT | 0.30 | 2.368 |
| 90 | 9000 | 0.010 | 80 | 1000 | PCT | −0.50 | 2.366 |
| 120 | 9000 | 0.013 | 80 | 1000 | PCT | 0.74 | 2.354 |
| 30 | 9000 | 0.003 | 80 | 1000 | HAST | −0.53 | 2.373 |
| 60 | 9000 | 0.007 | 80 | 1000 | HAST | 0.26 | 2.368 |
| 90 | 9000 | 0.010 | 80 | 1000 | HAST | 0.51 | 2.366 |
| 120 | 9000 | 0.013 | 80 | 1000 | HAST | 1.02 | 2.354 |

FIG. 10 shows the relation between the flow rate ratio of silane to nitrous oxide in the deposition and the density of the silicon oxynitride films. Triangular markers and square markers respectively represent samples obtained by deposition with a power of 150 W and samples obtained by deposition with a power of 1000 W. The samples with a power of 1000 W had higher density than those with a power of 150 W. At the same power, the density tended to increase as SiH₄/N₂O decreased.

FIG. 11 shows the relation between the density and swelling ratio of the silicon oxynitride films. A straight line 502 in the graph is an approximate straight line obtained from 15 samples and a correlation function R² is 0.801. Note that the approximate straight line and the correlation function were calculated excluding a point 501 which had a swelling ratio of more than 7 volume % and was considered an outlier. Thus, the density and the swelling ratio have a strong correlation: the higher the density was, the lower the swelling ratio tended to be.

This example showed that the silicon oxynitride film had higher density as SiH₄/N₂O decreased and power increased. It was also shown that the swelling ratio of the silicon oxynitride film decreased as its density increased.

### Example 2

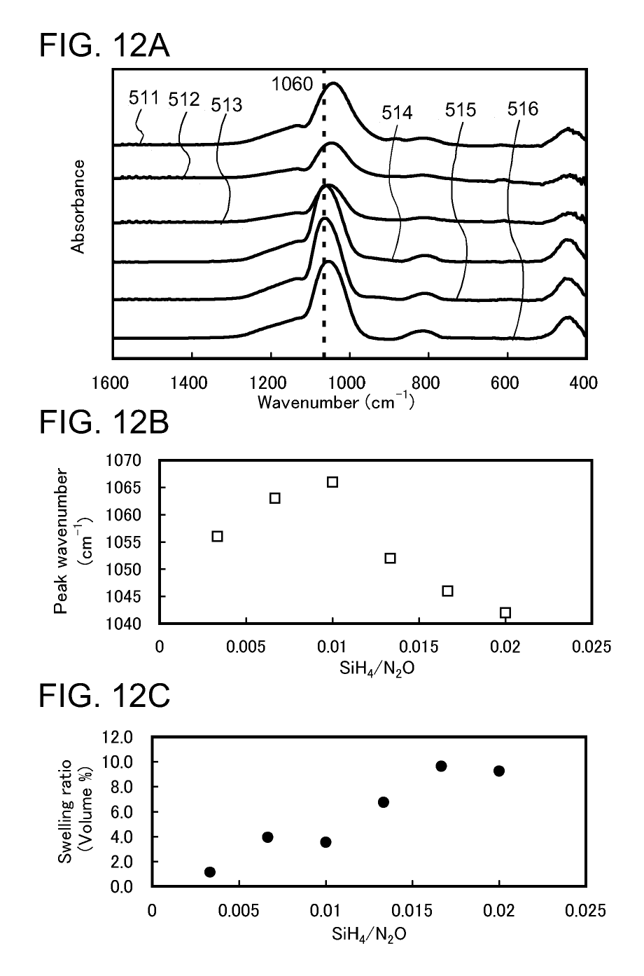

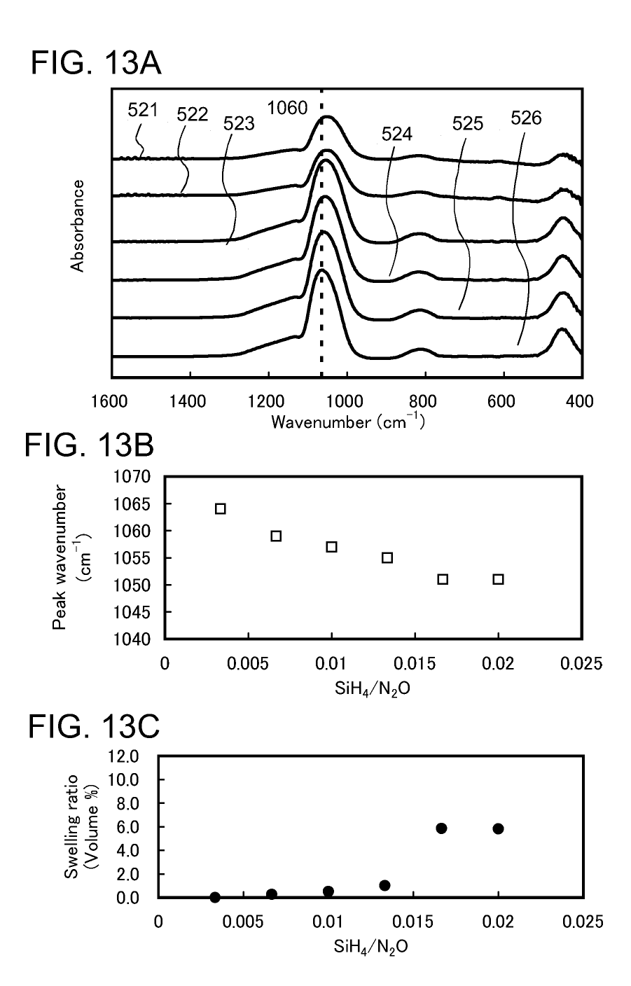

In this example, silicon oxynitride films were formed in a manner similar to that in Example 1. The results of measuring the infrared absorption spectra of the silicon oxynitride films by FT-IR (Fourier transform infrared spectroscopy), the swelling ratio of these films after the HAST, and the flow rate ratio of silane to nitrous oxide (SiH₄/N₂O) will be shown with reference to FIGS. 12A to 12C and FIGS. 13A to 13C.

The HAST was performed under the conditions similar to those in Example 1.

Table 2 shows specific conditions of deposition of the silicon oxynitride films, and the results of the FT-IR and the swelling ratio after the HAST.

TABLE 2

| | SiH₄ | | Peak wavenumber | Swelling ratio |
|---|---|---|---|---|
| Power [W] | [sccm] | N₂O [sccm] | [cm⁻¹] | [volume %] |
| 150 | 30 | 9000 | 1056 | 1.1 |
| 150 | 60 | 9000 | 1063 | 3.9 |
| 150 | 90 | 9000 | 1066 | 3.6 |
| 150 | 120 | 9000 | 1052 | 6.8 |
| 150 | 150 | 9000 | 1046 | 9.6 |
| 150 | 180 | 9000 | 1042 | 9.3 |
| 1000 | 30 | 9000 | 1064 | 0.0 |
| 1000 | 60 | 9000 | 1059 | 0.3 |
| 1000 | 90 | 9000 | 1057 | 0.5 |
| 1000 | 120 | 9000 | 1055 | 1.0 |
| 1000 | 150 | 9000 | 1051 | 5.9 |
| 1000 | 180 | 9000 | 1051 | 5.8 |

First, FIG. 12A shows the infrared absorption spectra of samples measured by the FT-IR. The samples were formed with a power of 150 W, a pressure of 80 Pa, and a substrate temperature (Tsub) of 220° C. while varying the flow rate ratio of silane to nitrous oxide. The horizontal axis represents wavenumber and the vertical axis represents absorbance. Specifically, the flow rate ratio of silane to nitrous oxide was varied as follows: the flow rate of N₂O was fixed to 9000 sccm in all the samples and the flow rate of SiH₄ was varied for each sample. In FIG. 12A, a curved line 511, a curved line 512, a curved line 513, a curved line 514, a curved line 515, and a curved line 516 denote the infrared absorption spectra of the samples with a flow rate ratio SiH₄/N₂O of 0.02, 0.016, 0.013, 0.01, 0.0066, and 0.0033, respectively.

A silicon atom and an oxygen atom in silicon oxynitride are bonded to each other and it is known that there are plural kinds of Si—O—Si bond modes: one is a stretching mode. In that case, an oxygen atom moves in the Si—O—Si bonding plane in the direction parallel to a line connecting a Si atom to another Si atom. The Si—O—Si bond stretching mode has an absorption near 1050 cm⁻¹. As an indication of this absorption, 1060 cm⁻¹ is denoted by a dotted line in FIG. 12A.

Another mode is a bending mode. In that case, an oxygen atom moves in the Si—O—Si bonding plane in the direction of the bisector of the angle of the Si—O—Si bond. The Si—O—Si bond bending mode has an absorption near 800 cm⁻¹. The other mode is a rocking mode. In that case, an oxygen atom moves away from the Si—O—Si bonding plane. The Si—O—Si bond rocking mode has an absorption near 450 cm⁻¹.

FIG. 12B shows the relation between the flow rate ratio SiH₄/N₂O of each sample in FIG. 12A and the peak wavenumber (maximum absorption wavenumber) of the Si—O—Si bond stretching mode. The horizontal axis represents SiH₄/N₂O and the vertical axis represents the peak wavenumber.

When the flow rate ratio SiH₄/N₂O was 0.01 or more, the Si—O—Si bond stretching mode had a peak at a higher wavenumber as SiH₄/N₂O was smaller. The peak was at 1056 cm⁻¹ or more in the case where SiH₄/N₂O was 0.01 or less. The peak was at 1052 cm⁻¹ or less in the case where SiH₄/N₂O was 0.013 or more. Specifically, the peak was at 1056 cm⁻¹ in the case where SiH₄/N₂O was 0.003, the peak was at 1063 cm⁻¹ in the case where SiH₄/N₂O was 0.007, the peak was at 1066 cm⁻¹ in the case where SiH₄/N₂O was 0.01, the peak was at 1052 cm⁻¹ in the case where SiH₄/N₂O was 0.013, the peak was at 1046 cm⁻¹ in the case where SiH₄/N₂O was 0.017, and the peak was at 1042 cm⁻¹ in the case where SiH₄/N₂O was 0.02.

The fact that the Si—O—Si bond stretching mode has a peak at a high wavenumber means that the bond distance between a Si atom and an 0 atom is short. In other words, it is said that a silicon oxynitride film has higher density as the Si—O—Si bond stretching mode has a peak at a higher wavenumber.

Next, the swelling ratio of each sample was measured by the HAST, and the results are shown in FIG. 12C. The horizontal axis represents SiH₄/N₂O and the vertical axis represents the swelling ratio.

The swelling ratio decreased as SiH₄/N₂O decreased. Particularly in the case where SiH₄/N₂O was 0.01 or less, the swelling ratio was 3.9 volume % or less.

FIG. 13A shows the infrared absorption spectra of samples measured by the FT-IR. In each of the samples, a silicon oxynitride film was formed in a manner similar to that in FIG. 12A except that the power in deposition was set to 1000 W. In FIG. 13A, a curved line 521, a curved line 522, a curved line 523, a curved line 524, a curved line 525, and a curved line 526 denote the infrared absorption spectra of the samples with a flow rate ratio SiH₄/N₂O of 0.02, 0.016, 0.013, 0.01, 0.0066, and 0.0033, respectively.

FIG. 13B shows the relation between the flow rate ratio SiH₄/N₂O of each sample in FIG. 13A and the peak wavenumber of the Si—O—Si bond stretching mode.

The Si—O—Si bond stretching mode had a peak at a higher wavenumber as SiH₄/N₂O was smaller. The peak was at 1057 cm⁻¹ or more in the case where SiH₄/N₂O was 0.01 or less. The peak was at 1055 cm⁻¹ or less in the case where SiH₄/N₂O was 0.013 or more. Specifically, the peak was at 1064 cm⁻¹ in the case where SiH₄/N₂O was 0.003, the peak was at 1059 cm⁻¹ in the case where SiH₄/N₂O was 0.007, the peak was at 1057 cm⁻¹ in the case where SiH₄/N₂O was 0.01, the peak was at 1055 cm⁻¹ in the case where SiH₄/N₂O was 0.013, the peak was at 1051 cm⁻¹ in the case where SiH₄/N₂O was 0.017, and the peak was at 1051 cm⁻¹ in the case where SiH₄/N₂O was 0.02.

A variation in the peak wavenumber with a variation in SiH₄/N₂O was smaller at a power of 1000 W than at a power of 150 W. For example, all of the samples with a flow rate ratio SiH₄/N₂O of 0.0066 to 0.02 inclusive had a peak at 1051 cm⁻¹ to 1059 cm⁻¹ inclusive.

Next, the swelling ratio of each sample was measured by the HAST, and the results are shown in FIG. 13C.

The swelling ratio decreased as SiH₄/N₂O decreased. At the same flow rate ratio SiH₄/N₂O, the swelling ratio was smaller at a power of 1000 W than at a power of 150 W. For example, in the case where SiH₄/N₂O was 0.013 or less, the swelling ratio was 1 volume % or less.

This example showed that the swelling ratio decreased as SiH₄/N₂O decreased. It was also shown that in the case where deposition is performed at a power of 1000 W, the Si—O—Si bond stretching mode had a peak at a higher wavenumber as SiH₄/N₂O decreased.

### Example 3

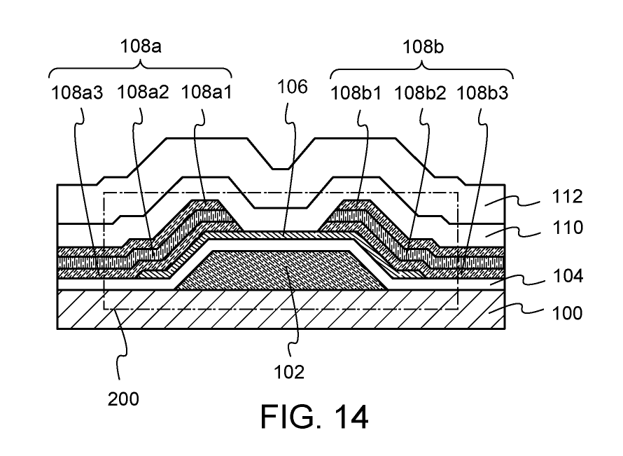

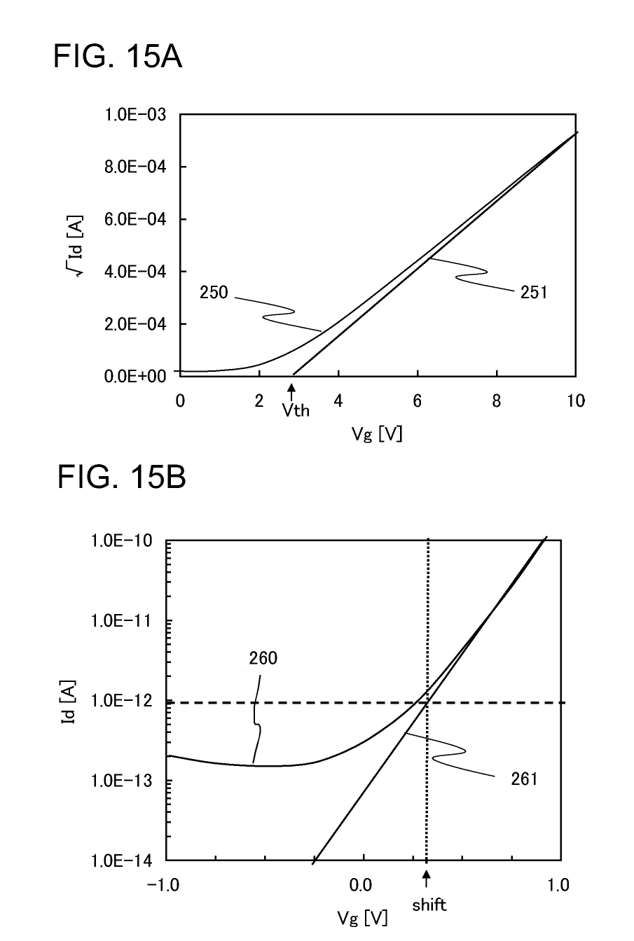

In this example, variations in the characteristics of transistors using the various kinds of silicon oxynitride films as protective films were measured. The measurement results will be shown with reference to FIG. 14, FIGS. 15A and 15B, FIG. 16, FIG. 17, and FIG. 18.

First, FIG. 14 shows a schematic diagram of a semiconductor device including the transistor 200 manufactured in this example. A glass substrate was used as the substrate 100 and a tungsten film (100 nm in thickness) was used as the gate electrode 102. As the gate insulating film 104, a silicon oxide film was formed by high-density plasma CVD. The oxide semiconductor film 106 was formed using an oxide semiconductor having a ratio of In:Ga:Zn=1:1:1 (atomic ratio). The source or drain electrode 108a was formed by stacking a titanium film (100 nm in thickness) as a conductive film 108a3, an aluminum film (400 nm in thickness) as a conductive film 108a2, and a titanium film (100 nm in thickness) as a conductive film 108a1. The drain or source electrode 108b was similarly formed by stacking the titanium film, the aluminum film, and the titanium film. A channel length L was set to 6 μm and a channel width W was set to 3 μm. As the first protective film 110, a silicon oxide film (400 nm in thickness) was formed by sputtering.

As the second protective film 112, various kinds of silicon oxynitride films (600 nm in thickness) were formed by changing the flow rate ratio of silane to nitrous oxide and the conditions of power.

A semiconductor device including the transistor 200 manufactured in the above manner was subjected to the PCT so that variations in characteristics were measured. The PCT was performed under the conditions similar to those in Example 1.

Here, a method for measuring variations in characteristics is described. The amount of change in the threshold voltage and shift value of a transistor between before and after the PCT is an important indicator for examining a variation in the characteristics of a transistor. Between before and after the PCT, a smaller amount of change in threshold voltage (Vth [V]) and shift value (Shift [V]) means a smaller variation in the characteristics of the transistor and higher reliability.

In this specification, in a curved line 250 where the horizontal axis and the vertical axis represent the gate voltage (Vg [V]) and the square root of drain current (Id^{1/2} [A]), respectively, the threshold voltage Vth is defined as the gate voltage at a point of intersection of an extrapolated tangent line 251 of Id^{1/2} having the highest inclination with the Vg axis (i.e., d^{1/2} of 0 A) (see FIG. 15A). Note that in this specification, the threshold voltage was calculated with a drain voltage Vd of 10 V.

In this specification, in a curved line 260 where the horizontal axis and the vertical axis represent the gate voltage (Vg [V]) and the logarithm of drain current (Id [A]), respectively, the shift value is defined as the gate voltage at a point of intersection of an extrapolated tangent line 261 of Id having the highest inclination with a straight line of Id=1.0×10⁻¹² [A] (see FIG. 15B). Note that in this specification, the shift value was calculated with a drain voltage Vd of 10 V.

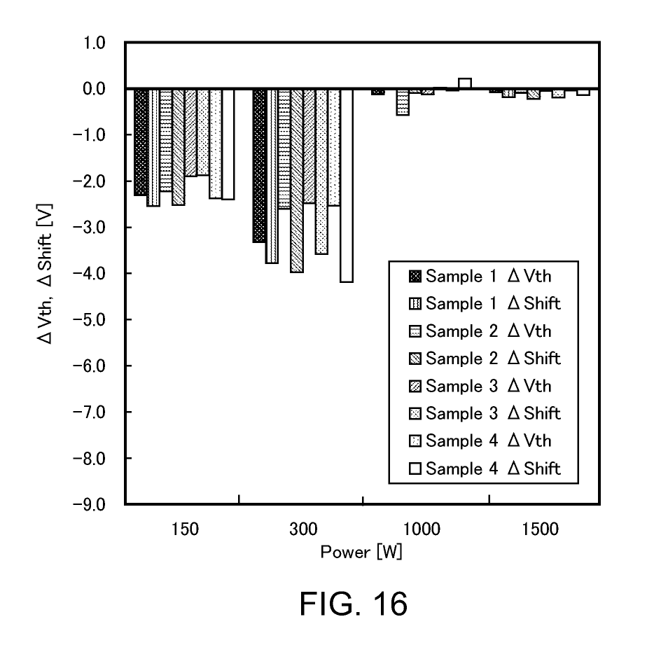

FIGS. 16 to 18 show the measurement results.

FIG. 16 shows the measurement results of the transistor including the second protective film 112. As the second protective film 112, various kinds of silicon oxynitride films were formed with the flow rate ratio of silane to nitrous oxide SiH₄/N₂O=90 sccm/9000 sccm while varying power. The horizontal axis represents the power and the vertical axis represents the amount of change in threshold voltage ΔVth and shift value ΔShift. The ΔVth and ΔShift of four samples are shown.

It was found that, in the case where the power was 1000 W or more, ΔVth and ΔShift were smaller than those in the case where the power was 300 W or less. The ΔVth and ΔShift of the samples with a power of 1000 W or more are so small that some of them cannot be represented by a bar graph. Note that the ΔVth and ΔShift of the samples with a power of 1000 W were as follows: Sample 1, ΔVth=−0.12 and ΔShift=0.01; Sample 2, ΔVth=−0.57 and ΔShift=−0.09; Sample 3, ΔVth=−0.12 and ΔShift=−0.02; and Sample 4, ΔVth=−0.04 and ΔShift=0.22. The ΔVth and ΔShift of the samples with a power of 1500 W were as follows: Sample 1, ΔVth=−0.08 and ΔShift=−0.19; Sample 2, ΔVth=−0.09 and ΔShift=0.22; Sample 3, ΔVth=−0.05 and ΔShift=−0.19; and Sample 4, ΔVth=−0.04 and ΔShift=−0.14.

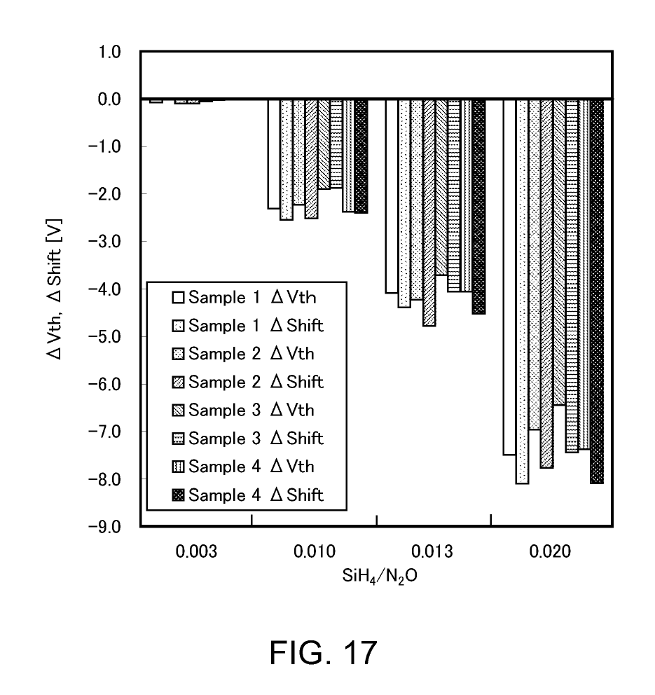

Next, various kinds of silicon oxynitride films were formed with a power of 150 W while varying SiH₄/N₂O. FIG. 17 shows the measurement results of the transistor using such silicon oxynitride films as the second protective film 112. The horizontal axis represents SiH₄/N₂O and the vertical axis represents ΔVth and ΔShift. The number of samples n was 4. Note that SiH₄/N₂O was varied in such a manner that the flow rate of N₂O was set to 9000 sccm and the flow rate of SiH₄ was varied.

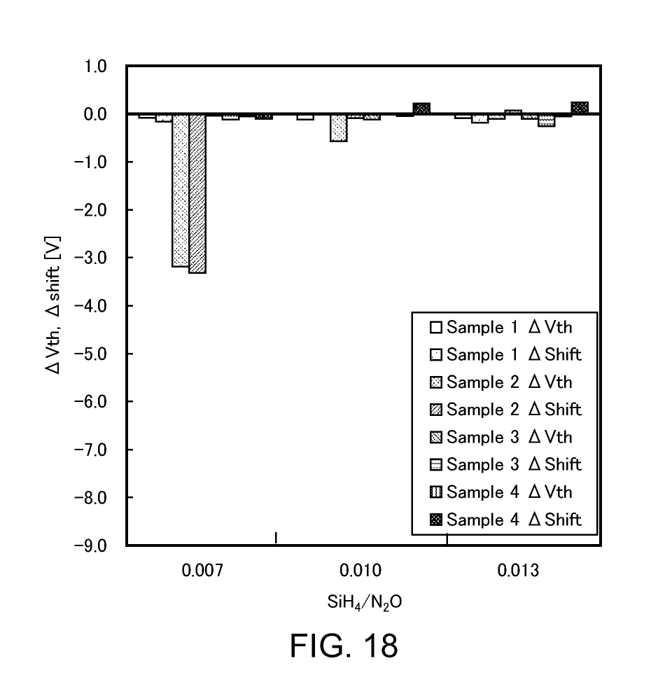

FIG. 18 shows the results of the measurement which was performed in a manner similar to that in FIG. 17 except that the power was set to 1000 W.

The results of FIG. 17 showed that ΔVth and ΔShift decreased as SiH₄/N₂O decreased. The ΔVth and ΔShift of the samples with a power of 150 W and a flow rate ratio SiH₄/N₂O of 0.003 are so small that some of them cannot be represented by a bar graph. Note that the ΔVth and ΔShift of the samples with a flow rate ratio SiH₄/N₂O of 0.003 were as follows: Sample 1, ΔVth=−0.07 and ΔShift=0.01; Sample 2, ΔVth=−0.1 and ΔShift=−0.1; Sample 3, ΔVth=−0.05 and ΔShift=−0.02; and Sample 4, ΔVth=−0.01 and ΔShift=−0.01. Further, the results of FIG. 17 and FIG. 18 showed that ΔVth and ΔShift were smaller at 1000 W than at 150 W. The ΔVth and ΔShift of the samples with a power of 1000 W are so small that some of them cannot be represented by a bar graph. Note that the ΔVth and ΔShift of the samples with a flow rate ratio SiH₄/N₂O of 0.007 were as follows: Sample 1, ΔVth=−0.08 and ΔShift=−0.16; Sample 2, ΔVth=−3.18 and ΔShift=−3.32; Sample 3, ΔVth=−0.04 and ΔShift=−0.12; and Sample 4, ΔVth=−0.05 and ΔShift=−0.1. Further, the ΔVth and ΔShift of the samples with a flow rate ratio SiH₄/N₂O of 0.010 were as follows: Sample 1, ΔVth=−0.12 and ΔShift=0.01; Sample 2, ΔVth=−0.57 and ΔShift=−0.09; Sample 3, ΔVth=−0.12 and ΔShift=0.02; and Sample 4, ΔVth=−0.04 and ΔShift=0.22. The ΔVth and ΔShift of the samples with a flow rate ratio SiH₄/N₂O of 0.013 were as follows: Sample 1, ΔVth=−0.08 and ΔShift=−0.18; Sample 2, ΔVth=−0.1 and ΔShift=0.07; Sample 3, ΔVth=−0.1 and ΔShift=−0.26; and Sample 4, ΔVth=−0.05 and ΔShift=0.24.

From the above examples 1 to 3, the following was found: a variation in the characteristics of the transistor was smaller as the silicon oxynitride film had higher density; the silicon oxynitride film had higher density as SiH₄/N₂O decreased; and the silicon oxynitride film had higher density as the power increased.

Specifically, in the case where the silicon oxynitride film was formed at a power of 150 W as shown in FIG. 17, a transistor with such a small variation in characteristics as an absolute value of ΔVth and ΔShift of 3 or less was obtained at a flow rate ratio SiH₄/N₂O of 0.01 or less. The swelling ratio of the silicon oxynitride film at a flow rate ratio SiH₄/N₂O of 0.01 or less was 4 volume % or less as shown in FIG. 12C. More specifically, in FIG. 12C, the swelling ratio was 1.1 volume % at SiH₄/N₂O of 0.0033, the swelling ratio was 3.9 volume % at SiH₄/N₂O of 0.0067, and the swelling ratio was 3.6 volume % at SiH₄/N₂O of 0.01. The density of the silicon oxynitride film with a swelling ratio of 4 volume % or less was 2.32 g/cm³ or more as shown in FIG. 11.

When the silicon oxynitride film was formed at a power of 1000 W, a transistor with a small variation in characteristics was obtained under any conditions as shown in FIG. 18. The swelling ratio in that case was 1.1 volume % or less as shown in FIG. 11. The density of the silicon oxynitride film with a swelling ratio of 1.1 volume % or less was 2.35 g/cm³ or more as shown in FIG. 11.

This application is based on Japanese Patent Application serial No. 2011-227163 filed with Japan Patent Office on Oct. 14, 2011, the entire contents of which are hereby incorporated by reference.

1. A semiconductor device comprising:
a transistor comprising:
a gate electrode;
an oxide semiconductor film including a channel formation region;
a gate insulating film between the gate electrode and the oxide semiconductor film; and
a source electrode and a drain electrode electrically connected to the oxide semiconductor film, and
a protective film overlapping with the oxide semiconductor film,
wherein the protective film comprises a silicon oxynitride film, and
wherein the silicon oxynitride film has a density of 2.32 g/cm³ or more.

2. The semiconductor device according to claim 1,
wherein the silicon oxynitride film has a swelling ratio of 4 volume % or less after a test at a temperature of 130° C. and a relative humidity of 100% for 12 hours, and
wherein the swelling ratio is obtained by an equation of (a first thickness of the silicon oxynitride film after the test−a second thickness of the silicon oxynitride film before the test)/(the second thickness of the silicon oxynitride film before the test)×100.

3. The semiconductor device according to claim 1,
wherein when a spectrum of the silicon oxynitride film is measured by Fourier transform infrared spectroscopy, a Si—O—Si bond stretching mode has a peak at 1056 cm⁻¹ or more.

4. The semiconductor device according to claim 1,
wherein the silicon oxynitride film is a film containing oxygen in the range of 50 at. % to 70 at. % inclusive, nitrogen in the range of 0.5 at. % to 15 at. % inclusive, silicon in the range of 25 at. % to 35 at. % inclusive, and hydrogen in the range of 0 at. % to 10 at. % inclusive.

5. The semiconductor device according to claim 1,
wherein the oxide semiconductor film comprises at least indium, zinc and oxygen.

6. The semiconductor device according to claim 1,
wherein the gate insulating film is in contact with the oxide semiconductor film, and
wherein the gate insulating film is a film from which oxygen is released by heat treatment.

7. The semiconductor device according to claim 1,
wherein the gate insulating film is in contact with the oxide semiconductor film, and
wherein the gate insulating film comprises at least one of silicon oxide, silicon oxynitride, silicon nitride oxide, aluminum oxide, aluminum oxynitride, gallium oxide, hafnium oxide, and yttrium oxide.

8. A semiconductor device comprising:
a transistor comprising:
a gate electrode;
an oxide semiconductor film including a channel formation region;
a gate insulating film between the gate electrode and the oxide semiconductor film; and
a source electrode and a drain electrode electrically connected to the oxide semiconductor film, and
a protective film overlapping with the oxide semiconductor film,
wherein the protective film comprises a silicon oxynitride film and an oxide film,
wherein the silicon oxynitride film has a density of 2.32 g/cm³ or more,
wherein the oxide film is in contact with a part of the oxide semiconductor film and provided between the oxide semiconductor film and the silicon oxynitride film, and
wherein a thickness of the silicon oxynitride film is 500 nm to 700 nm inclusive.

9. The semiconductor device according to claim 8,
wherein the silicon oxynitride film has a swelling ratio of 4 volume % or less after a test at a temperature of 130° C. and a relative humidity of 100% for 12 hours, and
wherein the swelling ratio is obtained by an equation of (a first thickness of the silicon oxynitride film after the test−a second thickness of the silicon oxynitride film before the test)/(the second thickness of the silicon oxynitride film before the test)×100.

10. The semiconductor device according to claim 8,
wherein when a spectrum of the silicon oxynitride film is measured by Fourier transform infrared spectroscopy, a Si—O—Si bond stretching mode has a peak at 1056 cm⁻¹ or more.

11. The semiconductor device according to claim 8,
wherein the silicon oxynitride film is a film containing oxygen in the range of 50 at. % to 70 at. % inclusive, nitrogen in the range of 0.5 at. % to 15 at. % inclusive, silicon in the range of 25 at. % to 35 at. % inclusive, and hydrogen in the range of 0 at. % to 10 at. % inclusive.

12. The semiconductor device according to claim 8,
wherein the oxide semiconductor film comprises at least indium, zinc and oxygen.

13. The semiconductor device according to claim 8,
wherein the gate insulating film is in contact with the oxide semiconductor film, and
wherein the gate insulating film is a film from which oxygen is released by heat treatment.

14. The semiconductor device according to claim 8,
wherein the gate insulating film is in contact with the oxide semiconductor film, and
wherein the gate insulating film comprises at least one of silicon oxide, silicon oxynitride, silicon nitride oxide, aluminum oxide, aluminum oxynitride, gallium oxide, hafnium oxide, and yttrium oxide.

15. The semiconductor device according to claim 8,
wherein the oxide film is a film from which oxygen is released by heat treatment.

16. The semiconductor device according to claim 8,
wherein the oxide film comprises at least one of silicon oxide, silicon oxynitride, silicon nitride oxide, aluminum oxide, aluminum oxynitride, gallium oxide, hafnium oxide, and yttrium oxide.

17. A method for manufacturing a semiconductor device, comprising the steps of:
forming a gate electrode;
forming a gate insulating film over the gate electrode;
forming an oxide semiconductor film over the gate insulating film;
forming a source electrode and a drain electrode over the oxide semiconductor film;
forming an oxide film over the source electrode and the drain electrode, wherein the oxide film is in contact with the oxide semiconductor film; and
forming a silicon oxynitride film over the oxide film by CVD at a flow rate ratio of silane to nitrous oxide of 0.01 or less, wherein the silicon oxynitride film has a density of 2.32 g/cm³ or more, and wherein a thickness of the silicon oxynitride film is 500 nm to 700 nm inclusive.

18. The method for manufacturing a semiconductor device, according to claim 17, further comprising performing a heat treatment after forming the oxide film, wherein oxygen is released from the oxide film and diffused into the oxide semiconductor film.

19. The method for manufacturing a semiconductor device, according to claim 17,
wherein the oxide film comprises at least one of silicon oxide, silicon oxynitride, silicon nitride oxide, aluminum oxide, aluminum oxynitride, gallium oxide, hafnium oxide, and yttrium oxide.
